(19) United States
(12) Patent Application Publication
(10) Pub. No.: US 2023/0268316 A1
(43) Pub. Date: Aug. 24, 2023

(54) PACKAGE STRUCTURE AND METHOD OF FORMING THE SAME

(71) Applicant: Taiwan Semiconductor Manufacturing Company, Ltd., Hsinchu (TW)

(72) Inventors: Sung-Yueh Wu, Chiayi County (TW); Chien-Ling Hwang, Hsinchu City (TW); Jen-Chun Liao, Taipei City (TW); Ching-Hua Hsieh, Hsinchu (TW)

(73) Assignee: Taiwan Semiconductor Manufacturing Company, Ltd., Hsinchu (TW)

(21) Appl. No.: 17/674,847

(22) Filed: Feb. 18, 2022

(51) Int. Cl. H01L 23/00; H01L 23/498; H01L 23/31; H01L 21/56

(52) U.S. Cl. CPC H01L 24/96; H01L 24/16; H01L 23/49822; H01L 23/3114; H01L 21/561; H01L 24/81; H01L 2224/16225; H01L 2224/81947

(57) ABSTRACT

A package structure includes a semiconductor device including a conductive feature, a joint layer, a pillar structure, an encapsulant and a RDL structure. The joint layer is disposed on the conductive feature. The pillar structure is disposed on and coupled to the semiconductor device through the joint layer. The encapsulant laterally encapsulates the semiconductor device and the pillar structure. The RDL structure is electrically connected to the semiconductor device.

### BACKGROUND

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are cross-sectional views illustrating a method of forming package structures according to some embodiments of the disclosure.

FIG. 2A to FIG. 2D are cross-sectional views illustrating a method of forming package structures according to some embodiments of the disclosure.

FIG. 3A to FIG. 3E are cross-sectional views illustrating a method of forming package structures according to some embodiments of the disclosure.

FIG. 4 illustrates a cross-sectional view of package structures according to some embodiments of the disclosure.

FIG. 5A to FIG. 5G are cross-sectional views illustrating a method of forming package structures according to some embodiments of the disclosure.

FIG. 6A and FIG. 6B illustrate cross-sectional views of package structures according to some embodiments of the disclosure.

FIG. 7A to FIG. 7D are cross-sectional views illustrating a method of forming package structures according to some embodiments of the disclosure.

FIG. 8A and FIG. 8G illustrate cross-sectional views of package structures according to some embodiments of the disclosure.

FIG. 9A and FIG. 9B are enlarged schematic views illustrating the mounting of the pillar structure to a semiconductor device according to various embodiments of the disclosure.

FIG. 9C to FIG. 9E are enlarged schematic views illustrating the position relationship of the encapsulant and the pillar structure having coating layer according to various embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “above”, “upper” and the like, may be used herein for ease of description to describe one element or feature's relationship to another element(s) or feature(s) as illustrated in the FIG.s. The spatially relative terms are intended to encompass different orientations of the device in use or operation in addition to the orientation depicted in the FIG.s. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Aspects of various embodiments are directed to provide pillar structures on semiconductor devices having different heights for providing more possible removal amount during planarization process and also compensating the height differences between the semiconductor devices. Among the various embodiments, like elements are designated with the same or similar reference numbers for ease of understanding and the details thereof are not repeated herein.

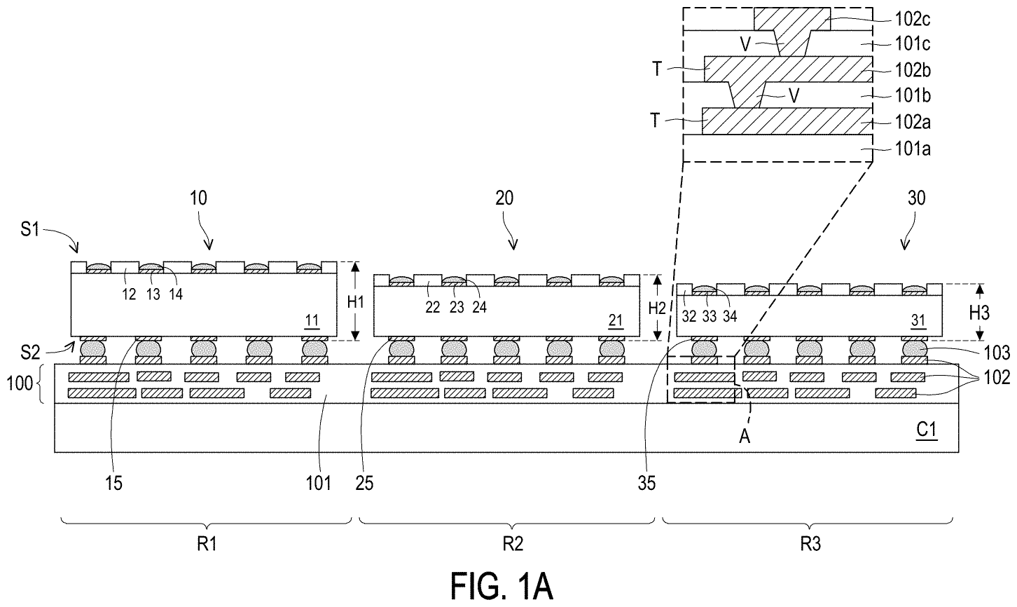

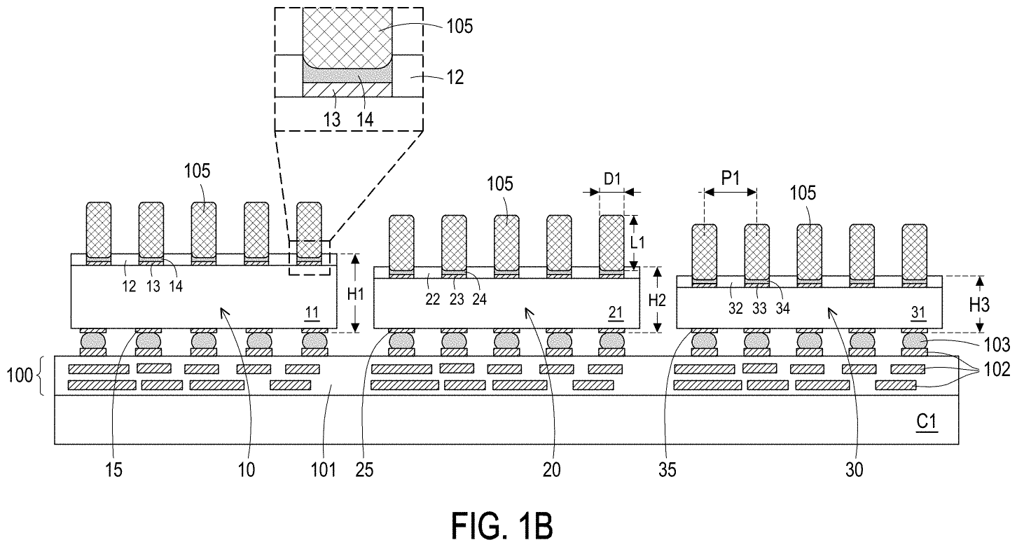

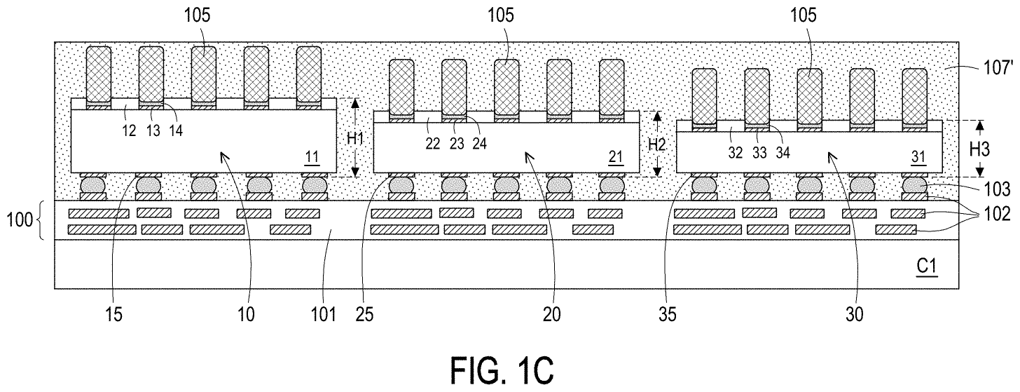

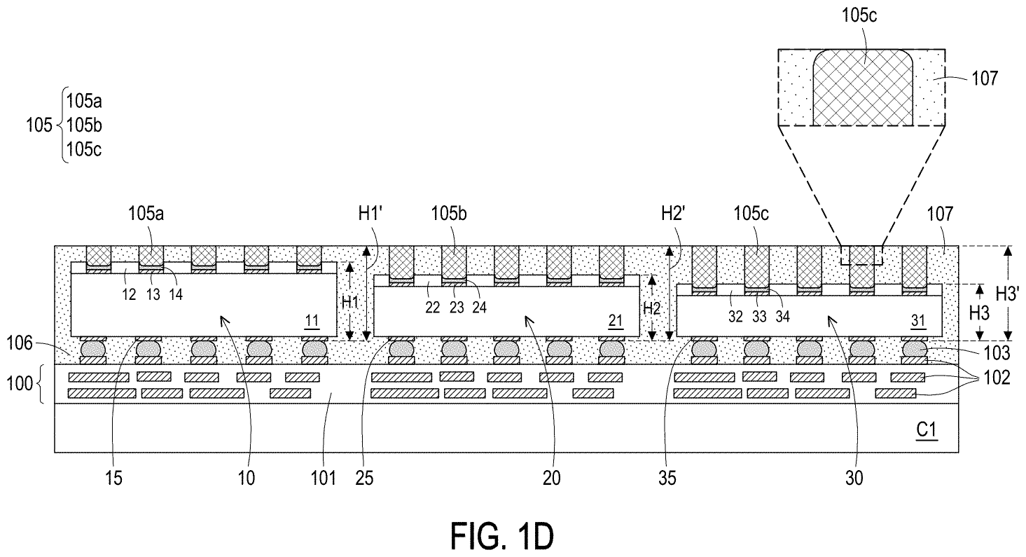

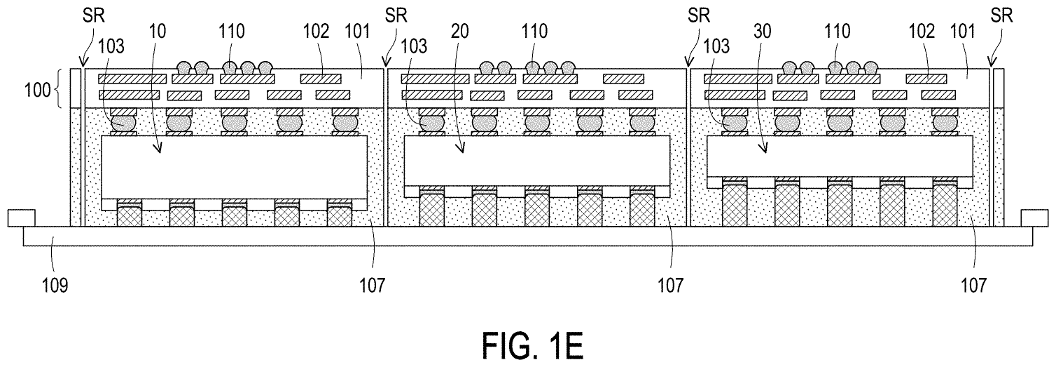

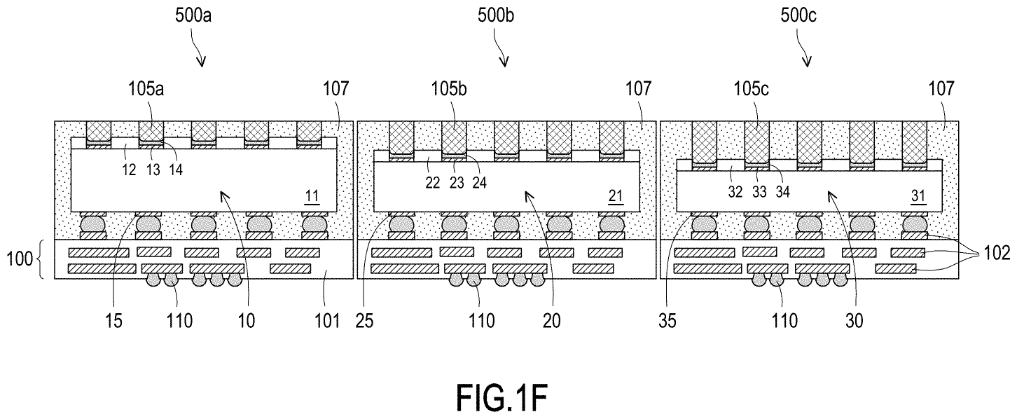

FIG. 1A to FIG. 1F are cross-sectional views illustrating a method of forming package structures according to some embodiments of the disclosure.

Referring to FIG. 1A, in some embodiments, a plurality of semiconductor devices 10, 20, and 30 are provided and electrically coupled to a package component 100. For example, a carrier C1 is provided. The carrier C1 may be a glass carrier, a ceramic carrier, or the like. A de-bonding layer (not shown) may be disposed on the carrier C2. In some embodiments, the de-bonding layer may be formed of an adhesive such as an Ultra-Violet (UV) glue, a Light-to-Heat Conversion (LTHC) glue, or the like, or other types of adhesives. The de-bonding layer may be decomposable under the heat of light to thereby release the carrier C1 from the overlying structures that will be formed in subsequent steps. In some embodiments, the carrier C1 includes a plurality of package regions, such as including the package regions R1-R3, on which a plurality of package structures are to be formed. It is noted that, the number of the package regions shown in the figures are merely for illustration, and the disclosure is not limited thereto. In some embodiments, the package regions are arranged in an array including a plurality of rows and columns, for example.

The package component 100 is disposed over the carrier C1. The package component 100 may include a body structure 101 and a plurality of conductive features 102 embedded in and/or protruding from the body structure 101. The conductive features 102 may include multiple conductive layers that are connected to each other through conductive vias. For example, the package component 100 may be a redistribution layer (RDL) structure 100 including a plurality of dielectric layers and redistribution layers alternately stacked over the carrier C1. In such embodiments, the dielectric layers constitute the body structure 101, while the conductive features 102 are the redistribution layers. However, the disclosure is not limited thereto. In some other embodiments, the package component 100 may be an interposer or any other suitable package component including conductive features therein.

In some embodiments in which the package component 100 is a RDL structure, as shown in the enlarged view of the region A of the RDL structure 100, the RDL structure 100 may include dielectric layers 101a, 101b, 101c and redistribution layers 102a, 102b, 102c. It is noted that, the number of the dielectric layers and redistribution layers shown in the figure is merely for illustration, and the disclosure is not limited thereto.

In some embodiments, the dielectric layer 101a is formed over the carrier C1, and the redistribution layer 102a may be disposed on and extending along the top surface of the dielectric layer 101a. The redistribution layer 102b penetrates through the dielectric layer 101b and is electrically connected to the redistribution layer 102a. The redistribution layer 102c penetrates through the dielectric layer 101c and is electrically connected to the redistribution layer 102b.

In some embodiments, the topmost redistribution layer (e.g., the redistribution layer 102c) may include a plurality of conductive pads for external connection. The redistribution layer 102c may protrude from the top surface of the dielectric layer 101c and exposed, that is, the top surface of the redistribution layer 102c may be higher than the top surface of the dielectric layer 101c, but the disclosure is not limited thereto. In some other embodiments, the top surface of the redistribution layer 102c may be substantially level with the top surface of the dielectric layer 101c.

In some embodiments, the RDL structure 100 includes a plurality of vias V and a plurality of traces T connected to each other. For example, the redistribution layers 102a and 102b respectively include traces T extending along the top surfaces of the dielectric layers 101a and 101b. The redistribution layer 102b includes vias V that disposed between the traces T of the redistribution layers 102a and 102b, such that the traces T of the redistribution layers 102a and 102b are electrically connected to each other through the vias V. The redistribution layer 102c may include vias V and pad portions that are disposed on the vias V and electrically connected to the redistribution layer 102b through the vias V. In the illustrated embodiment, the bottommost redistribution layer (e.g., redistribution layer 102a) may be free of vias, but the disclosure is not limited thereto. In alternative embodiments, the redistribution layer 102a may further include vias underlying the traces 102a and penetrating through the dielectric layer 101a for further connection.

In some embodiments, the dielectric layers 101a-101c may respectively includes a polymer material such as polybenzoxazole (PBO), polyimide (PI), benzocyclobutene (BCB), the like, or combinations thereof. The forming methods of the dielectric layers 101a-101c include suitable fabrication techniques such as spin coating, chemical vapor deposition (CVD), plasma-enhanced chemical vapor deposition (PECVD), lamination or the like. In some embodiments, the redistribution layers 102a-102c respectively includes conductive materials. The conductive material includes metal such as copper, nickel, titanium, a combination thereof or the like, and may be formed by an electroplating process. In some embodiments, the redistribution layers 102a-102c respectively includes a seed layer (not shown) and a metal layer formed thereon (not shown). The seed layer may be a metal seed layer such as a copper seed layer. In some embodiments, the seed layer includes a first metal layer such as a titanium layer and a second metal layer such as a copper layer over the first metal layer. The metal layer may be copper or other suitable metals.

In some embodiments, a plurality of semiconductor devices 10, 20, 30 are disposed on the RDL structure 100 by, for example, pick-and-place process, and may be electrically connected to the RDL structure 100 through a plurality of connectors 103. The semiconductor devices 10-30 may respectively be or include a semiconductor die (e.g., application-specific integrated circuit (ASIC) chip, a system on chip (SoC), an analog chip, a sensor chip, a wireless and radio frequency chip, a voltage regulator chip, a memory chip, a high bandwidth memory (HBM) chip), a semiconductor package (e.g., fan-out package, PoP, 3DIC, chip-on-wafer (CoW), chip-on-wafer-on-substrate (CoWoS), or the like), package substrate (e.g., circuit board), memory device (e.g., dynamic random access memory (DRAM)), sensor, optical component, passive component (e.g., integrated passive device (IPD)), or the like, or any other suitable type of semiconductor device. The semiconductor devices 10-30 may be the same types of devices or different types of devices. The semiconductor devices 10-30 are disposed within the package regions R1-R3, respectively. In some embodiments, one semiconductive device corresponds to one package region, but the disclosure is not limited thereto. In some other embodiments, more than one semiconductor device may be disposed within one package region.

In some embodiments, the semiconductor device 10 includes a body structure 11 having a first side S1 and a second side S2 opposite to each other. A plurality of conductive features 13 and 15 are respectively disposed on the first side S1 and the second side S2 of the body structure 11. The conductive features 13 and 15 may be or include conductive pads, conductive pillars, conductive bumps, or the like, or combinations thereof. The material of the conductive features 13 and 15 may include metal, metal alloy, such as aluminum, copper, the like, alloys thereof, or combinations thereof. A passivation layer 12 may be disposed on the first side S1 of the body structure 11 and laterally covering sidewalls of the conductive features 13. The passivation layer 12 includes a dielectric material, such as silicon oxide, silicon nitride, a polymer material (e.g., PI, PBO, BCB), or the like, or combinations thereof. In some embodiments, there may be free of passivation layer disposed on the second side S2 of the body structure 11, but the disclosure is not limited thereto. In some other embodiments, a passivation layer may also be disposed on the second side S2 of the body structure 11 to cover sidewalls of the conductive features 15.

In some embodiments, the body structure 11 includes a plurality of conductive features (e.g., conductive wirings, conductive vias, connectors, or the like or combinations thereof that are connected to each other) embedded therein and electrically connect the conductive features 13 on the first side S1 to the conducive features 15 on the second side S2. The body structure 11 may include or free of devices. The devices (e.g., integrated circuit devices) may include active devices, passive devices, or combinations thereof, such as, transistors, capacitors, resistors, diodes, photodiodes, fuse devices, or the like, or combinations thereof.

In some embodiments, joint layers 14 may be disposed on the conductive features 13 for further electrical connection. The joint layer 14 may include solder paste, other metallic paste, such as silver or copper paste, flux, conductive glue, or the like, or combinations thereof. The joint layer 14 may be formed by any suitable process, such as printing, plating, jetting, spin coating, spray coating, or the like. In some embodiments, as shown in FIG. 1A, the top surface of the passivation layer 12 may be higher than the top surfaces of the conductive features 13 and the joint layer 14, but the disclosure is not limited thereto. In some other embodiment, the top surface of the passivation layer 12 may be level with or lower than the top surfaces of the conductive features 13 and/or the top surfaces of joint layers 14. In some embodiments, the top surfaces of the joint layers 14 may protrude from the top surface of the passivation layer 12.

Still referring to FIG. 1A, the semiconductor devices 20 and 30 may include structures similar to that of the semiconductor device 10. For example, the semiconductor device 20 includes a body structure 21 having a first side S1 and a second side S2, a plurality of conductive features 23 and 25 respectively disposed on the first side S1 and the second side S2 of the body structure 21, and a passivation layer 22 laterally aside the conductive features 23, and joint layers 24 are disposed on the conductive features 23 for further connection. The semiconductor device 30 includes a body structure 31 having a first side S1 and a second side S2, a plurality of conductive features 33 and 35 respectively disposed on the first side S1 and the second side S2 of the body structure 31, and a passivation layer 32 laterally aside the conductive features 33, and joint layers 34 are disposed on the conductive features 33. The components of semiconductor devices 20 and 30 are similar to those described with respect to the semiconductor device 10, which are not described again here. It is noted that, the number of the semiconductor devices shown in the figure is merely for illustration, and the disclosure is not limited thereto. More or less semiconductor device may be disposed on the RDL structure 100. Further, the first side S1 and second side S2 of the semiconductor devices 10-30 may be active side and non-active side of the semiconductor devices 10-30, respectively, or vice versa.

In some embodiments, the semiconductor devices 10-30 may have different dimensions (e.g., height, width, footprint, or the like). The height may also be referent to as thickness. For example, the heights of the semiconductor devices 10-30 may be different from each other. The height H1 of the semiconductor device 10 may be larger than the height H2 of the semiconductor device 20, and the height H2 of the semiconductor device 20 may be larger than the height H3 of the semiconductor device 30. The top surfaces (e.g., topmost surfaces) of semiconductor devices 10-30 may be located at different level heights. For example, the topmost surface of the semiconductor device 10 may be higher than the topmost surface of the semiconductor device 20, and the topmost surface of the semiconductor device 20 may be higher than the topmost surface of the semiconductor device 30. In some embodiments, the bottommost surface of the semiconductor devices 10-30 may be substantially level with each other or located at different level heights.

In some embodiments, the heights H1, H2, H3 of the semiconductor devices 10-30 may each range from 50 μm to 2000 μm. the height difference (or referred to as thickness deviation) between the semiconductor devices 10-30 (e.g., H1-H2, H2-H3, H1-H3, or the vertical distance between the top surfaces of the semiconductor devices) may range from 0-500 μm, for example.

Referring to FIG. 1A and FIG. 1B, in some embodiments, a plurality of pillar structures 105 are mounted to the semiconductor devices 10-30. For example, the pillar structures 105 are electrically bonded to the conductive features 13, 23, 33 of the semiconductor devices 10, 20, 30 through the joint layers 14, 24, 34, respectively. In some embodiments, after the joint layers 14, 24, 34 are disposed on the front sides S1 of the semiconductor devices 10-30, the pillar structures 105 are placed on the corresponding joint layers 14-34, and a curing process or a reflow process is then performed to complete the joint of the pillar structures 105. The joint layers 14-34 are sandwiched between the pillar structures 105 and the conductive features 13-33 and cover the bottom surfaces of the pillar structures 105. In some embodiments, the joint layers 14-34 may further extend to cover portions of the sidewalls of the pillar structures 105.

In some embodiments, the pillar structures 105 have substantially the same heights, and the top surfaces of the pillar structures 105 are located at different level heights due to the height difference between the underlying semiconductor devices 10-30. However, the disclosure is not limited thereto. In alternative embodiments, pillar structures with different heights may also be used. In some embodiment, the height L1 of the pillar structure 105 may range from 100 μm to 1000 μm, the width D1 of the pillar structure 105 may range from 50 μm to 1000 μm, the aspect ratio of the pillar structure 105 (e.g., L1/D1) may range from 1-10, for example. In some embodiments, the pillar structures 105 disposed on a same semiconductor device may have a pitch ranging from 100 μm to 5000 μm, for example. The term “pitch” described herein refers to a width of the feature plus the distance to the next immediately adjacent feature.

In some embodiments, the pillar structures 105 include metallic materials, such as metal or metal alloy, and may be applied for thermal conduction, electrical conduction, magnetic field transceiving, or the like, or combinations thereof. For example, the pillar structures 105 may include copper, aluminum, tungsten, iron, or the like, or combinations thereof. In some embodiments, the pillar structures 105 may also be referred to as conductive pillars. In some embodiments, the pillar structures 105 may be applied for optical signal transmitting, and the materials of the pillar structures 105 may include silica, fiber, or the like.

In some embodiments, the cross-sectional shape of the pillar structure 105 may be rectangle with rounding corners (as shown in FIG. 1B), rectangle with right corners, square with rounding corners or right corners, or any other suitable shape. In some embodiments, the joint layers 14-34 are disposed between the pillar structures 105 and the conductive features 13-33, and may further extend to cover the bottom corners of the pillar structures 105, respectively. A portion of the joint layer 14-34 covering the bottom corner of the pillar structure 105 may be disposed laterally between the pillar structure 105 and the passivation layer 12-32. In such embodiments, the edge portion of the joint layer 14-34 covering the bottom corner of the pillar structure 105 may be thicker than the middle portion of the joint layer 14-34 disposed between the middle portion of pillar structure 105 and the conductive feature 13-33. In some embodiments, the width of the pillar structure 105 may be substantially the same as the width of the corresponding conductive feature 13-33, but the disclosure is not limited thereto. In some other embodiments, the width of the pillar structure 105 may be less than or larger than the width of the corresponding conductive feature 13-33.

Through mounting the pillar structures 105 to the semiconductor devices 10-30, the heights of the semiconductor devices 10-30 are increased. The increased heights may provide increased possible removal amount for subsequently planarization process.

Referring to FIG. 1C, in some embodiments, an encapsulant material 107′ is formed over the RDL structure 100 to encapsulate the semiconductor devices 10-30 and the pillar structures 105. The encapsulant material 107′ may extend to fill the spaces between the semiconductor devices 10-30 and the RDL structure 100. In some embodiments, the encapsulant 107′ includes a molding compound, a molding underfill, a resin such as epoxy, a combination thereof, or the like. In some other embodiments, the encapsulant 107′ includes a photo-sensitive material such as polybenzoxazole (PBO), polyimide (PI), benzocyclobutene (BCB), a combination thereof, or the like. In alternative embodiments, the encapsulant 107′ includes nitride such as silicon nitride, oxide such as silicon oxide, phosphosilicate glass (PSG), borosilicate glass (BSG), boron-doped phosphosilicate glass (BPSG), a combination thereof, or the like.

In some embodiments, the encapsulant 107′ includes a molding underfill which is a composite material including a base material (such as polymer) and a plurality of fillers distributed in the base material. The fillers may include a single element, a compound such as nitride, oxide, or a combination thereof. The fillers may include silicon oxide, aluminum oxide, boron nitride, alumina, silica, or the like, or combinations thereof, for example. In some embodiments, the fillers are spherical particles, or the like. The cross-section shape of the fillers may be circle, oval, or any other suitable shape. In some embodiments, the fillers include solid fillers, hollow fillers, or a combination thereof. In some embodiments, the filler content and/or filler size of the encapsulant material 107′ are selected, such that the encapsulant material 107′ is able to extend to the spaces between the semiconductor devices 10-30 and the RDL structure 100.

In some embodiments, the encapsulant material 107′ may be formed to have a top surface higher than top surfaces of all the pillar structures 105, and the top surfaces of all the pillar structures 105 are covered by the encapsulant material 107′, but the disclosure is not limited thereto. In some other embodiments, one or more of the pillar structures 105 may be exposed by the encapsulant material 107′, and the encapsulant material 107′ may be formed to have a top surface lower than and/or level with one or more of the pillar structures 105.

Referring to FIG. 1C and FIG. 1D, a planarization process is then performed to remove a portion of the encapsulant material 107′ and portions of the pillar structures 105, such that an encapsulant 107 is formed, and the top surfaces of the pillar structures 105 are exposed by encapsulant 107. In some embodiments, the top surfaces of the pillar structures 105 may be substantially level with the top surface of the encapsulant 107. The planarization process may include a grinding process, a polishing process, such as a chemical mechanical polishing (CMP) process, or the like, or combinations thereof.

Referring to FIG. 1D, the encapsulant 107 encapsulate sidewalls and top surfaces of the semiconductor devices 10-30, sidewalls of the pillar structures 105, and may fill the space between the semiconductor devices 10-30 and the RDL structure 100 to encapsulate bottom surfaces of the semiconductor devices 10-30, the connectors 103 and the topmost conductive features 102 of the RDL structure 100.

During the planarization process, the removal amounts of the pillar structures 105 on different semiconductor devices 10-30 are different from each other. For example, the removal amount of the pillar structure 105 on the semiconductor device 10 having the highest top surface is the largest, and the removal amount of the pillar structure 105 on the semiconductor device 30 having the lowest top surface is the least. In some embodiments, the removal amount of the pillar structure 105 on the semiconductor device 10 is larger than the removal amount of the pillar structure 105 on the semiconductor device 20, and the removal amount of the pillar structure 105 on the semiconductor device 20 is larger than the removal amount of the pillar structure 105 on the semiconductor device 30.

In some embodiments in which the cross-sectional shapes of the pillar structures 105 are rectangle with rounding corners, the top rounding corners of one or more of the pillar structures 105 may be removed by the planarization process, and the remained pillar structure 105 may have rounding bottom corners and right top corners. In some embodiments, the rounding top corners of some of the pillar structures 105 may be not removed. For example, the planarization process may be stopped when the top surfaces of the pillar structures at lowest level height (e.g., pillar structures 105 on the semiconductor device 30) are exposed, and the rounding top corners of the said pillar structures would be remained, as shown in the enlarged view of FIG. 1D.

Still referring to FIG. 1D, after the planarization process is performed, the pillar structures 105 include pillar structure 105a on the semiconductor device 10, pillar structures 105b on the semiconductor device 20 and pillar structures 105c on the semiconductor device 30. In some embodiments, the top surfaces of the pillar structures 105a, 105b, 105c are substantially level with each other. The height HE of the semiconductor device 10 with the pillar structures 105a, the height H2′ of the semiconductor device 20 with the pillar structures 105b, and the height H3′ of the semiconductor device 30 are substantially the same. In other words, the height (e.g., H3′-H3) of pillar structure 105c is larger than the height (e.g., H2′-H2) of the pillar structure 105b, and the height (e.g., H2′-H2) of the pillar structure 105b is larger than the height (e.g., H1′-H1) of the pillar structure 105a. In some sense, the pillar structures 105a-105c are configured for compensating the height difference between the semiconductor devices 10-30.

Referring to FIG. 1D and FIG. 1E, in some embodiments, the structure shown in FIG. 1C is flipped upside down and mounted to a frame tape 109. The carrier C1 is then released from the structure. For example, the de-bonding layer (not shown) disposed between the carrier C1 and the RDL structure 100 is decomposed under the heat of light, and the carrier C1 is then released from the structure. As such, the RDL structure 100 faces up and the top surface of the dielectric layer 101 is exposed.

In some embodiments, a plurality of the connectors 110 are disposed on the RDL structure 100 to electrically connect to the conductive features 102 of the RDL structure 100. For example, a patterning process (e.g., including lithography and etching processes) may be performed to form a plurality of openings (e.g., via holes) in the dielectric layer 101, so as to expose portions of the conductive features 102. Thereafter, the connectors 110 are formed on the conductive features 102 exposed by the openings of the dielectric layer 101. The connectors 110 may include solder bumps, solder balls, copper bumps, or any other suitable metallic bumps or balls, or combinations thereof. In some embodiments in which the connectors 110 are solder regions, a under-ball metallurgy (UBM) layer (not shown) may further be formed before forming the connectors 110. The connectors 110 are electrically connected to the RDL structure 100 and further electrically connected to the semiconductor devices 10, 20, 30 through the RDL structure 100. In some embodiments, the connectors 110 may also be referred to as conductive terminals. In some embodiments, the dimension of the connector 110 is less than the dimension of the connector 103. However, the disclosure is not limited thereto. In some other embodiments, the dimension of the connector 110 may be substantially the same as or larger than the dimension of the connector 103.

Referring to FIG. 1E and FIG. 1F, thereafter, a singulation process may be performed on the structure along scribe lines/regions SR to singulate the package structures including the semiconductor devices 10, 20, 30. The singulation process may include a mechanical saw process, laser dicing process, or the like, or combinations thereof. Thereafter, the package structures are removed from the frame tape 109.

Referring to FIG. 1F, the package structures 500a, 500b, 500c respectively including the semiconductor devices 10, 20, 30 are thus formed. The package structure 500a includes the semiconductor 10, the pillar structures 105a, the encapsulant 107, the RDL structure 100, and the connectors 110. The semiconductor device 10 is electrically bonded to the RDL structure 100 through the connectors 103. The pillar structures 105 are coupled to the semiconductor device 10 through the joint layers 14. The encapsulant 107 encapsulate the semiconductor device 10 and the sidewalls of the pillar structures 105a. The package structures 500b and 500c have similar structures, which are not described again here.

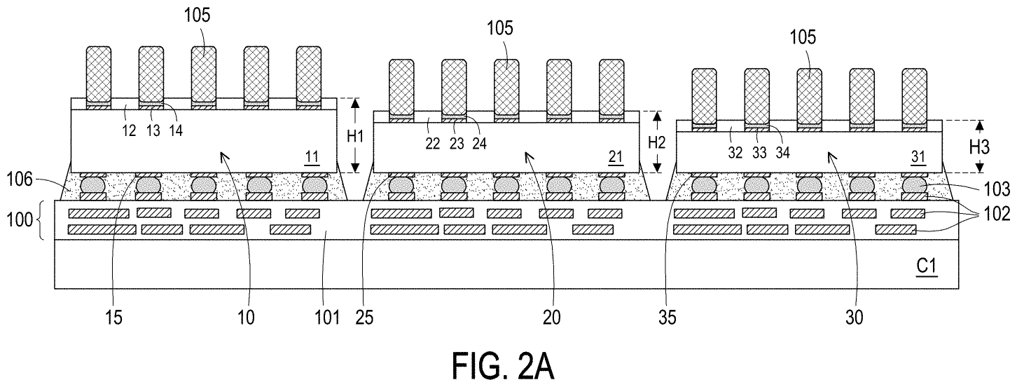

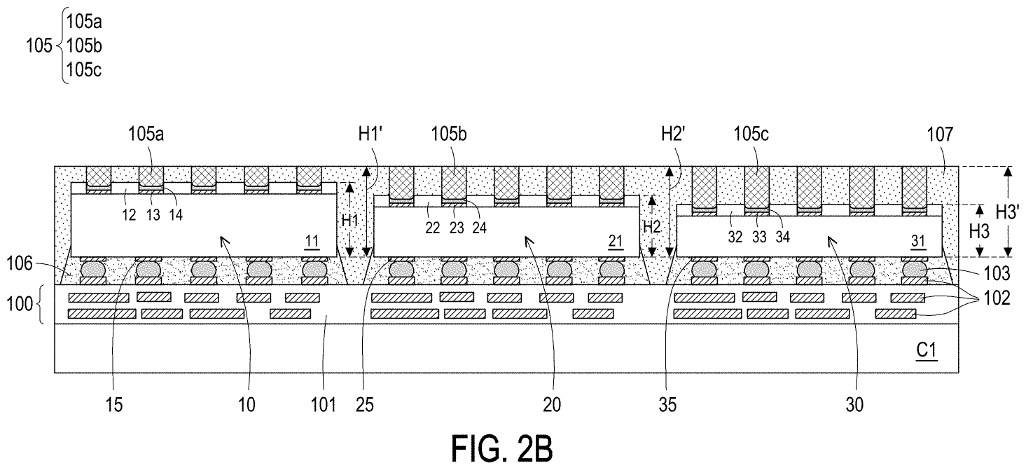

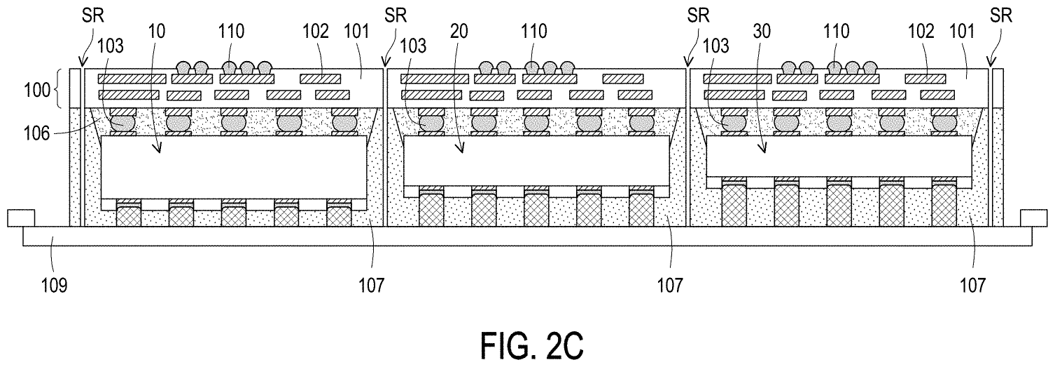

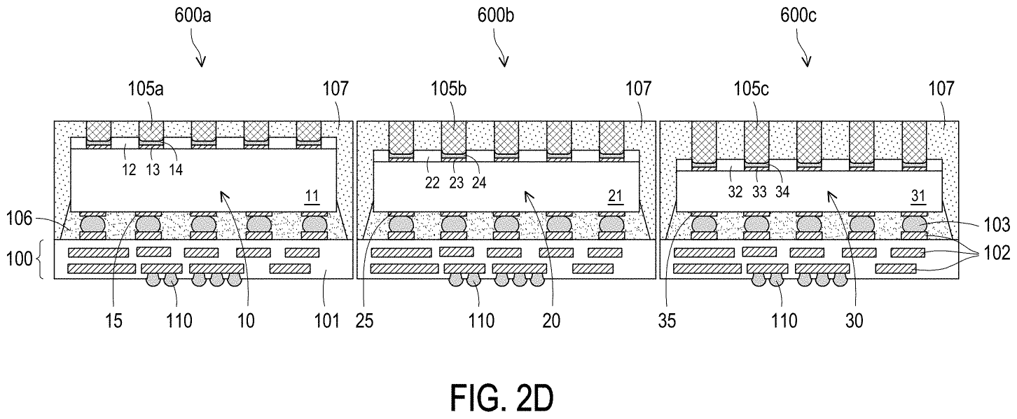

FIG. 2A to FIG. 2D are cross-sectional views illustrating a method of forming package structures according to alternative embodiments of the disclosure. The present embodiment is similar to the foregoing embodiment, except that the package structures further include underfill layers disposed between the semiconductor devices and the RDL structure.

Referring to FIG. 2A, in some embodiments, before the encapsulant material is formed, underfill layers 106 are formed to fill the spaces between the semiconductor devices 10-30 and the RDL structure 100. The underfill layers 106 may be formed by a dispensing process followed by a curing process. In some embodiments, the underfill layers 106 cover bottom surface of the semiconductor devices 10-30, portions of the top surface of the RDL structure 100, and laterally surround the connectors 103 and the conductive features 15-35 and 102. In some embodiments, the underfill layers 106 may further extend to cover sidewalls of the semiconductor devices 10-30, but the disclosure is not limited thereto.

Referring to FIG. 2A and FIG. 2B, thereafter, processes similar to those described in FIG. 1C to FIG. 1D are performed to form an encapsulant 107. For example, an encapsulant material may be formed over the RDL structure 100 to encapsulate the underfill layers 106, the semiconductor devices 10-30, and the pillar structures 105. Thereafter, a planarization process may be performed to remove a portion of the encapsulant material and portions of the pillar structures 105, such that the top surfaces of the pillar structures 105 are exposed.

In some embodiments, the material of the encapsulant 107 in the present embodiment may be selected from the same candidate materials of the above-described encapsulant material 107′, but may be the same as, similar to or different from the above-described encapsulant material 107′. For example, the encapsulant 107 may include a molding compound which is a composite material. The molding compound may include a base material (such as polymer) and a plurality of fillers distributed in the base material. In some embodiments, the underfill layer 106 may also include a base material (such as polymer, epoxy, or the like) and fillers distributed in the base material, and the dimension (e.g., diameter, width, etc.,) and/or filler content of the fillers included in the underfill layer 106 may be less than those of the fillers included in the encapsulant 107. In some other embodiments, the underfill layer 106 may be free of fillers.

Referring to FIG. 2B to FIG. 2D, thereafter, processes similar to those described in FIG. 1D to FIG. 1F are performed. The structure shown in FIG. 2B is flipped upside down and mounted to a frame tape 109, the carrier C1 is released, and a plurality of connectors 110 are formed on the RDL structure 100. Thereafter, a singulation process is performed along the scribe regions SR to singulate the package structures. The package structures are then removed from the frame tape 109.

Referring to FIG. 2D, the package structures 600a-600c are thus formed. The package structures 600a-600c are similar to the package structures 500a-500c, except that the package structures 600a-600c further include underfill layers 106 disposed between the semiconductor devices 10-30 and the RDL structure 100, and the sidewalls of underfill layers 106 are encapsulated by the encapsulant 107.

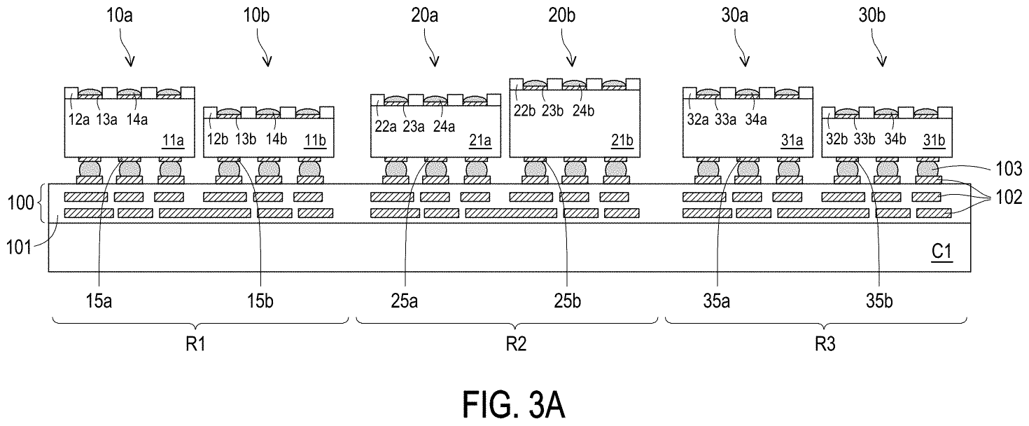

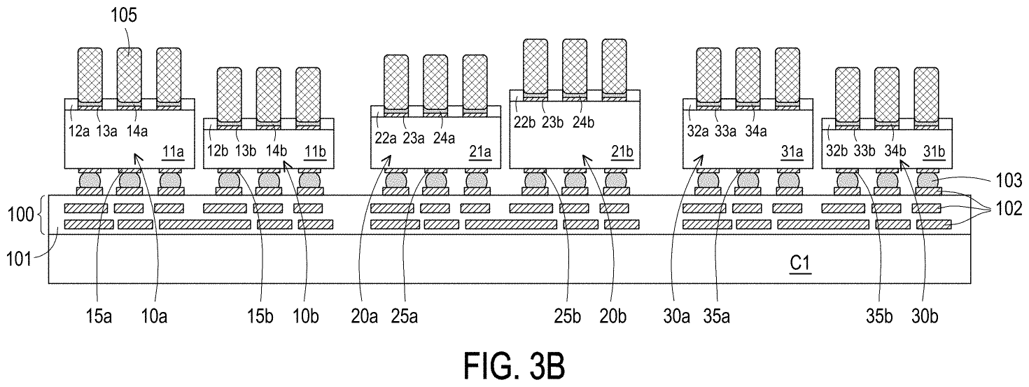

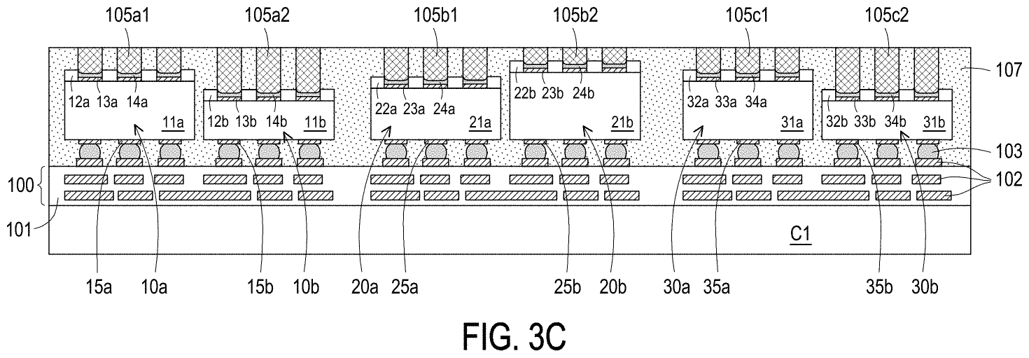

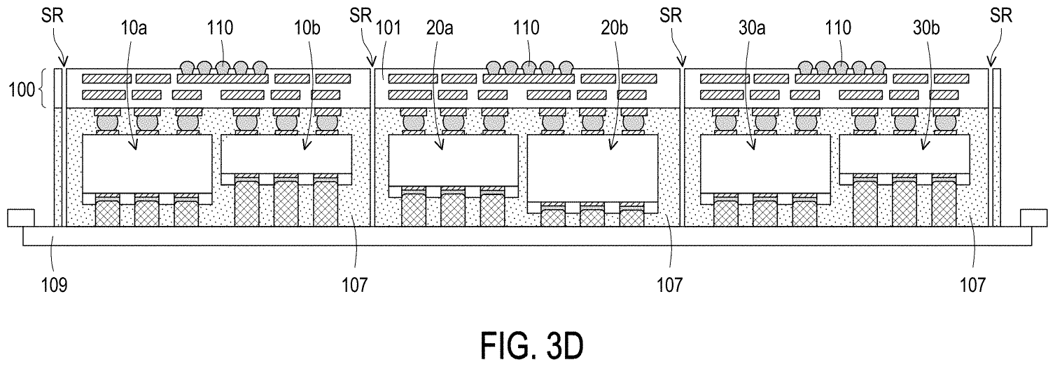

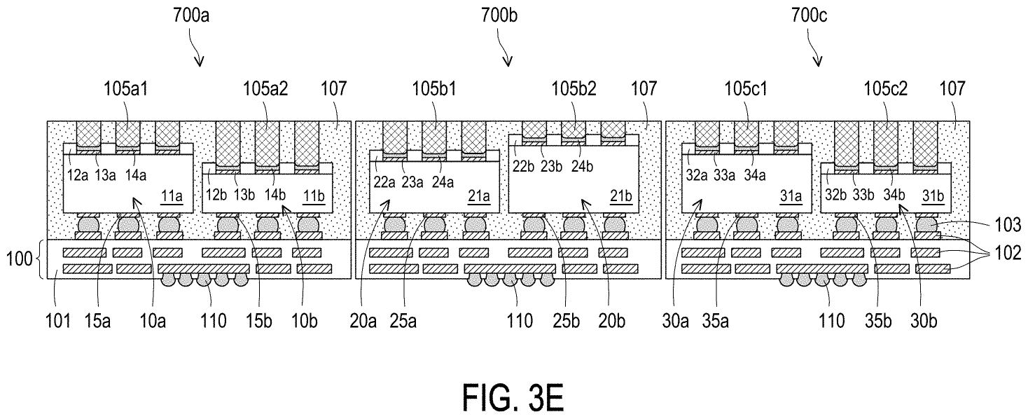

FIG. 3A to FIG. 3E are cross-sectional views illustrating a method of forming package structures according to some other embodiments of the disclosure. The present embodiment is similar to the foregoing embodiments, except that the formed package structure includes more than one semiconductor devices.

Referring to FIG. 3A, in some embodiments, a carrier C1 is provided, and a RDL structure 100 is formed over the carrier C1. In some embodiments, the carrier C1 includes a plurality of package region R1, R2, R3 on which a plurality of package structures are to be formed.

In some embodiments, more than one semiconductor device may be bonded to the RDL structure 100 within the respective package regions R1-R3. For example, semiconductor devices 10a and 10b are bonded to the RDL structure 100 within the package region R1, semiconductor devices 20a and 20b are bonded to the RDL structure 100 within the package region R2, and semiconductor devices 30a and 30b are bonded to the RDL structure 100 within the package region R3. The structures of the semiconductor devices 10a-30b are similar to those of the semiconductor devices 10-30 described in the foregoing embodiment, which are not described again here. It is noted that, the number of the package regions, and the number of semiconductor devices disposed in respective package regions shown in the figures are merely for illustration, and the disclosure is not limited thereto. Any suitable number of package regions may be disposed, and any suitable number of semiconductor devices may be disposed within the respective package regions, and the number of semiconductor devices disposed in different package regions may be the same or different, depending on the product design and requirement.

In some embodiments, the semiconductor devices 10a, 10b, 20a, 20b, 30a, 30b have different heights, and the top surfaces thereof are located at different level heights. The bottom surfaces (e.g., bottommost surfaces) of the semiconductor devices 10a-30b may be substantially level with each other, but the disclosure is not limited thereto. In some embodiments, joint layers 14a, 14b, 24a, 24b, 34a, 34b are disposed on the conductive features 13a, 13b, 23a, 23b, 33a, 33b of the semiconductor devices 10a, 10b, 20a, 20b, 30a, 30b, respectively.

Referring to FIG. 3A and FIG. 3B, a plurality of pillar structures 105 are mounted to the semiconductor devices 10a-30b through the joint layers 14a-34b, respectively. The pillar structures 105 may have substantially the same heights, and top surfaces of the pillar structures 105 may be located at different level heights due to the height difference between the underlying semiconductor devices 10a-30b.

Referring to FIG. 3B and FIG. 3C, thereafter, an encapsulant material is formed over the RDL structure 100 to encapsulate the semiconductor devices and the pillar structures 105. A planarization process is then performed to remove a portion of the encapsulant material and portions of the pillar structures 105. As a result, pillar structures 105a1, 105a2, 105b1, 105b2, 105c1, 105c2 are remained on the semiconductor devices 10a, 10b, 20a, 20b, 30a, 30b, respectively, and an encapsulant 107 is formed to encapsulate the semiconductor devices and the pillar structures. In some embodiments, the topmost surfaces of the pillar structures 105a1-205c2 and the top surface of the encapsulant 107 are substantially level with each other.

Referring to FIG. 3C to FIG. 3E, the structure shown in FIG. 3C is flipped upside down and mounted to a frame tape 109, and the carrier C1 is released. A plurality of connectors 110 are formed on and electrically connected to the RDL structure 100, and further electrically connected to the semiconductor devices 10a-30b through the RDL structure 100. Thereafter, a singulation process is performed along scribe regions SR disposed between the package regions R1-R3, so as to singulate the package structures 700a, 700b, 700c, and the package structures 700a-700b may be removed from the frame tape 109.

Referring to FIG. 3E, in some embodiments, the package structures 700a-700c may each include more than one semiconductor devices. For example, the package structure 700a includes the semiconductor devices 10a and 10b, the pillar structures 105a1 and 105a2, the encapsulant 107, the RDL structure 100 and the connectors 110. The semiconductor devices 10a and 10b may be coupled to (e.g., electrically coupled to) each other through the RDL structure 100. The package structure 700b and 700c have similar structures, except that the semiconductor devices are replaced by the semiconductor devices 20a/20b, 30a/30b, and the pillar structures are replaced by the pillar structures 105b1/105b2, 105c1/105c2. The structural features of the package structure 700a-700c are described as below taken the package structure 700a as an example, and it should be understood that the package structures 700b-700c have similar features.

In some embodiments, the semiconductor devices 10a and 10b may be the same types of semiconductor devices or different types of devices. In some embodiments, the semiconductor devices 10a and 10b are two small device partitions with different functions of a larger single semiconductor device. The semiconductor devices 10a and 10b may have different dimensions (e.g., height, width, footprint, etc.,). For example, the height of the semiconductor device 10a may be larger than the height of the semiconductor device 10b. In some embodiments, the top surface of the semiconductor device 10a (e.g., the top surface of the passivation layer 12a or the conductive feature 13a) is higher than the top surface of the semiconductor device 10b (e.g., the top surface of the passivation layer 12b or the conductive feature 13b). In some embodiments, the bottom surfaces (e.g., bottommost surfaces) of the semiconductor devices 10a and 10b may be substantially level with each other or located at different level heights.

The pillar structures 105a1 and 105a2 are disposed on the semiconductor devices 10a and 10b, and are coupled to the semiconductor devices 10a and 10b through the joint layers 14a and 14b, respectively. In some embodiments, the pillar structures 105a1 and 105a2 have substantially coplanar top surfaces and different heights. For example, the height of the pillar structure 105a2 disposed on lower semiconductor device 10b is larger than the height of the pillar structure 105a1 disposed on higher semiconductor device 10a. The bottom surface of the pillar structure 105a2 is lower than the bottom surface of the pillar structure 105a1. In some embodiments, the semiconductor devices 10a/10b with pillar structures 105a1/105a2 may also be referred to as reconstructed semiconductor devices. For example, the semiconductor device 10a with the pillar structures 105a1 disposed thereon may be referred to as a first reconstructed semiconductor device, while the semiconductor device 10b with the pillar structures 105a2 disposed thereon may be referred to a second reconstructed semiconductor device, or vice versa. The first reconstructed semiconductor device and the second reconstructed semiconductor device have top surfaces that are substantially level with each other, and may have substantially the same heights.

The semiconductor devices 10a and 10b are electrically coupled to the RDL structure 100 through the connectors 15a and 15b, respectively. The encapsulant 107 is disposed on the RDL structure 100 and encapsulate sidewalls and top surfaces of the semiconductor devices 10a and 10b, and sidewalls of the pillar structures 105a1 and 105a2. In some embodiments, the encapsulant 107 may further extend to fill the space between the semiconductor devices 10a/10b and the RDL structure 100.

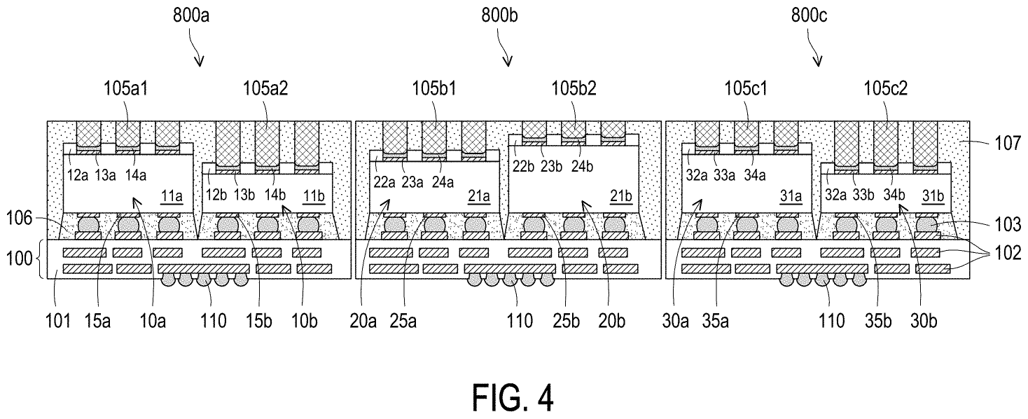

FIG. 4 is a cross-sectional view illustrating package structures 800a-800c according to an alternative embodiment of the disclosure. The package structures 800a-800c are similar to the package structures 700a-700c, except that the package structures 800a-800c further include underfill layers.

Referring to FIG. 4, in some embodiments, underfill layers 106 are disposed to fill the spaces between the semiconductor devices and the RDL structure 100. Taken the package structure 800a as an example, the underfill layers 106 are disposed to fill the spaces between the semiconductor devices 10a/10b and the RDL structure 100, and the sidewalls of the underfill layers 106 are encapsulated by the encapsulant 107. In some embodiments, the underfill layers between different semiconductor devices 10a/10b and the RDL structure 100 may be laterally spaced from each other or merged with each other.

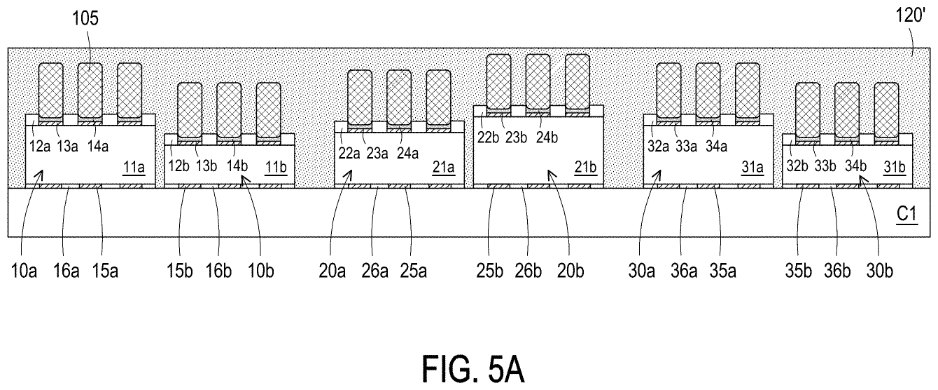

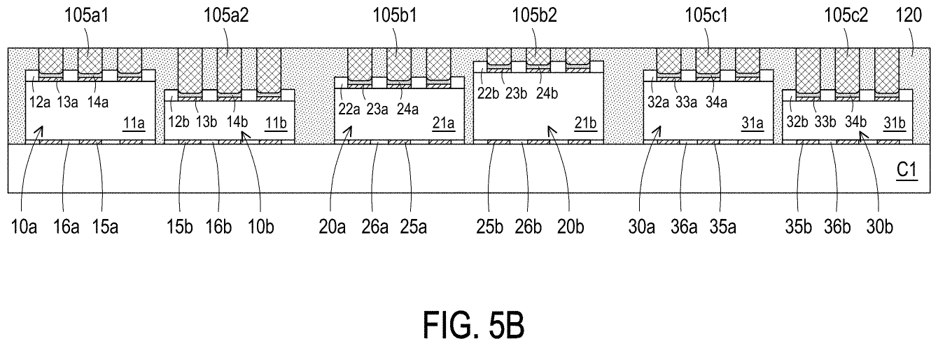

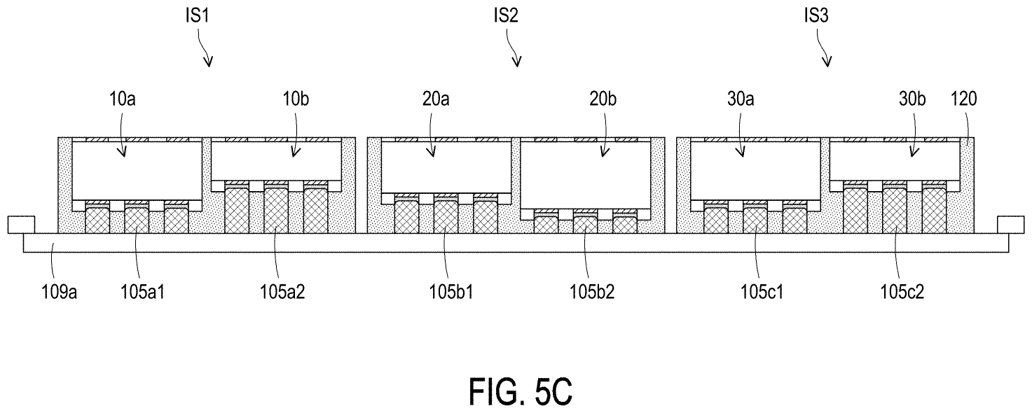

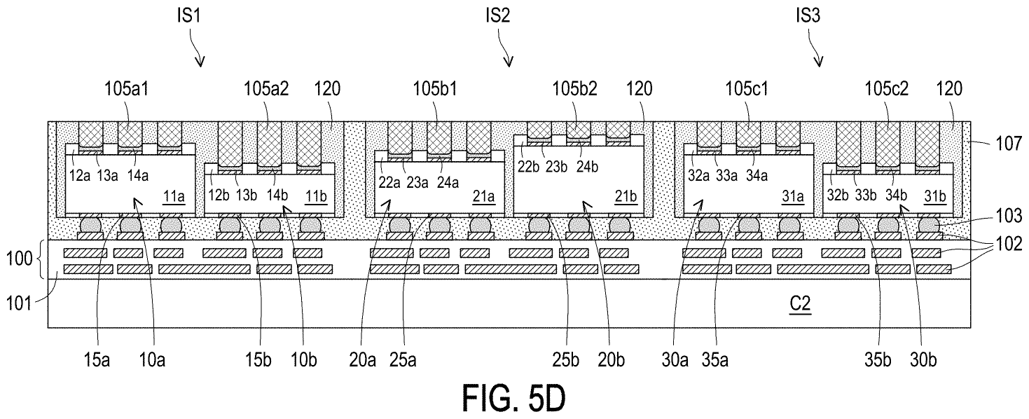

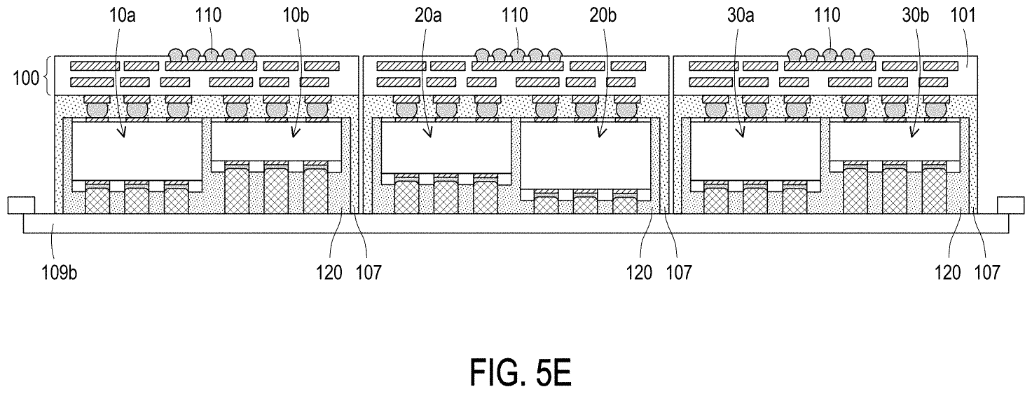

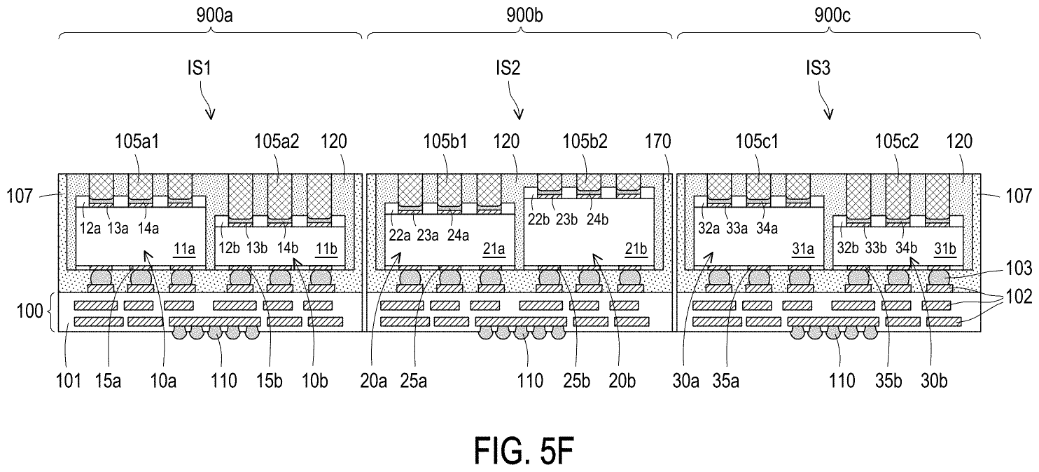

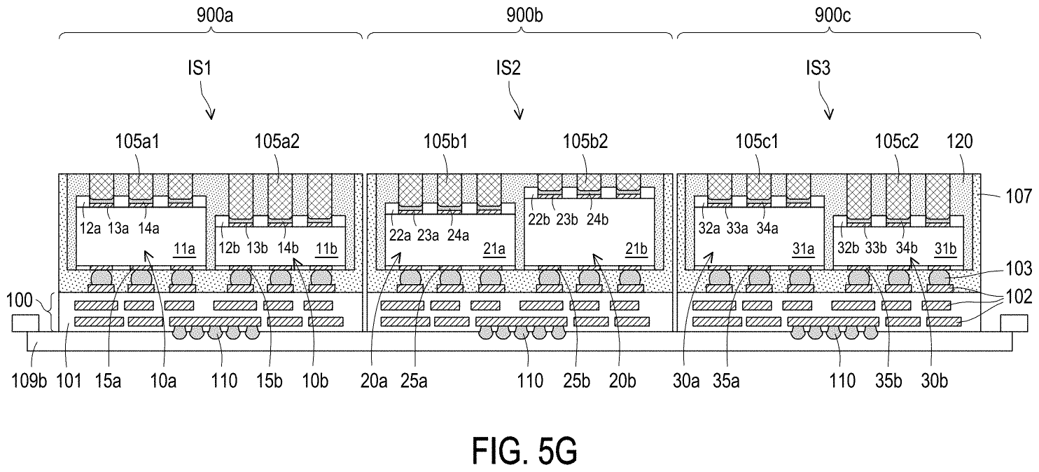

FIG. 5A to FIG. 5G are cross-sectional views illustrating a method of forming package structures according to some other embodiments of the disclosure. The present embodiment is similar to the foregoing embodiments, except that the semiconductor devices are pre-leveled and/or pre-molded before bonded to a RDL structure.

Referring to FIG. 5A, in some embodiments, semiconductor devices 10a-30b are disposed on a carrier C1. The semiconductor devices 10a-30b may be attached to the carrier C1 through an adhesive layer (not shown), such as a die attach film (DAF), silver paste, or the like. In such embodiment, the semiconductor devices 10a-30b may further include passivation layers 16a, 16b, 26a, 26b, 36a, 36b disposed on the second sides of the body structures 11a, 11b, 21a, 21b, 31a, 31b and laterally surrounding the conductive features 15a, 15b, 25a, 25b, 35a, 35b, respectively. The material of the passivation layers 16a-36b may be selected from the same candidate materials of the passivation layers 12a-32b.

The semiconductor devices 10a-30b may have different heights and top surfaces thereof may be located at different level heights. The bottom surfaces of the semiconductor devices 10a-30b are attached to the carrier C1 and may be substantially level with each other. A plurality of the pillar structures 105 are disposed on and coupled to the semiconductor devices 10a-30b, and an encapsulant material 120′ is formed over the carrier C1 to encapsulate the semiconductor devices 10a-30b and the pillar structures 105.

Referring to FIG. 5A to FIG. 5B, a planarization process is performed to planarize the top surfaces of the pillar structures 105 and the encapsulant material 120′. A portion of the encapsulant material 120′ and portions of the pillar structures 105 are removed, and pillar structures 105al, 105a2, 105b1, 105b2, 105c1, 105c2 are remained on the semiconductor devices 10a, 10b, 20a, 20b, 30a, 30b, respectively. An encapsulant 120 is formed to encapsulate sidewalls and top surfaces of the semiconductor devices 10a-30b and sidewalls of the pillar structures 105a1-105c2. In some embodiments, the top surfaces of the pillar structures 105a1-105c2 and the top surface of the encapsulant 107 are substantially level or coplanar with each other.

Referring to FIG. 5B and FIG. 5C, the structure shown in FIG. 5B is flipped upside down and placed on a frame tape 109a. The carrier C1 is released from the structure. In some embodiments, a singulation process is then performed on the structure to form a plurality of semiconductor structures IS1, IS2, IS3 that are separated from each other. The semiconductor structures IS1, IS2, IS3 may also be referred to as intermediate structures or sub-package structures.

In some embodiments, the semiconductor structures IS1 includes the semiconductor devices 10a and 10b, pillar structures 105a1 and 105a2, and the encapsulant 120. The semiconductor structures IS2 includes the semiconductor devices 20a and 20b, pillar structures 105b1 and 105b2, and the encapsulant 120. The semiconductor structures IS3 includes the semiconductor devices 30a and 30b, pillar structures 105c1 and 105c2, and the encapsulant 120. The semiconductor structures IS1-IS3 have substantially the same heights, and the bottom surfaces and the top surfaces of the semiconductor structures IS1-IS3 are substantially level or coplanar with each other. It is noted that, the number of semiconductor devices that included in the semiconductor structure shown in the figures is merely for illustration. The semiconductor structures IS1-IS3 may each include more or less semiconductor devices (e.g., one semiconductor device or more than two semiconductor devices) therein.

Referring to FIG. 5C and FIG. 5D, a carrier C2 is provided, and a RDL structure 100 is formed over the carrier C2. Thereafter, the semiconductor structures IS1, IS2, IS3 are bonded to the RDL structure 100 through a plurality of connectors 103. In some embodiments, an encapsulant 107 is then formed over the RDL structure 100 to laterally encapsulate the semiconductor structures IS1-IS3. The encapsulant 107 may further extend to fill the spaces between the semiconductor structures IS1-IS3 and the RDL structure 100 to laterally surround the connectors 103 and/or the conductive features 102 of the RDL structure 100. In some embodiments, the encapsulant 107 may be formed by forming an encapsulant material over the RDL structure 100 to cover the sidewalls and top surfaces of the semiconductor structures IS1-IS3, followed by a planarization process (e.g., CMP) performed to remove excess portions of the encapsulant material over the top surfaces of the semiconductor structures 151453. In some embodiments, the top surface of the encapsulant 107 is substantially level with the top surfaces of the semiconductor structures IS1-IS3.

Referring to FIG. 5D, in some embodiments, the encapsulant 107 encapsulates sidewalls of the encapsulants 120 of the semiconductor structures IS1-IS3, and the encapsulant 120 is interposed between the respective semiconductor devices 10a-30b and the encapsulant 107, and between the respective pillar structures 105a1-105c2 and the encapsulant 107. In other words, the semiconductor devices 10a-30b and the pillar structures 105a1-105c2 are separated from the encapsulant 107 by the encapsulant 120 therebetween. In the present embodiment, the passivation layers 15a-35b of the semiconductor devices 10a-30b are laterally encapsulated by the encapsulant 120, and the bottom surfaces of the passivation layers 15a-35b may be covered by and in physical contact with the encapsulant 107.

Referring to FIG. 5D to FIG. 5F, the structure shown in FIG. 5D is flipped upside down and mounted to a frame tape 109b, and the carrier C2 is released. Thereafter, a plurality of connectors 110 are formed on and electrically connected to the RDL structure 100, and further electrically connected to the semiconductor devices 10a-30b through the RDL structure 100. A singulation process is then performed to singulate the package structures. The separate package structures are then removed from the frame tape 109b.

Referring to FIG. 5F, package structures 900a-900c are thus formed. The package structures 900a-900c are similar to the package structures 700a-700c, except that the package structures 900a-900c further include the encapsulant 120 and the passivation layers 15a-35b. As shown in FIG. 5F, the encapsulant 120 encapsulate the respective semiconductor devices and pillar structures, and the sidewalls and bottom surface of the encapsulant 120 may be encapsulated by the encapsulant 107. In some embodiments, the sidewalls of the RDL structure 100 may laterally extend beyond the sidewalls of the encapsulant 120 and may be substantially aligned with the sidewalls of the encapsulant 107.

In the embodiments of the disclosure, the processes shown in FIG. 5A to FIG. 5C may also be referred to as a first packaging process, and the processes shown in FIG. 5D to FIG. 5F may also be referred to as a second packaging process. During the first packaging process, the semiconductor devices 10a-30b having different heights are pre-leveled and are packaged in semiconductor structures IS1-IS3 having substantially the same heights. During the second packaging process, the semiconductor structures IS1-IS3 with substantially the same heights are coupled to the RDL structure and packaged in the package structures 900a-900c. In the present embodiment, the planarization of the semiconductor devices with pillar structures are performed during the first packaging process in which the structure over the carrier may be relatively thin, which may reduce or avoid the warpage of the structure.

FIG. 5G illustrates an alternative process for forming the package structures 900a-900c.

In some embodiments, the second packaging process may omit the using of a second carrier, and may be directly performed on a frame tape. For example, referring to FIG. 5C and FIG. 5G, after the semiconductor structures IS1-IS3 are formed in FIG. 5C, a RDL structure 100 with connectors 110 pre-formed thereon may be disposed on the frame tape 109b. Subsequent processes, such as bonding the semiconductor structures IS1-IS3 to the RDL structure 100, formation of the encapsulant 107, and the singulation process are then performed, with the structure disposed over the frame tape 109b. Afterwards, the package structures may be removed from the frame tape 109b. In such embodiment, the resulted package structures 900a-900c are substantially the same as those described in FIG. 5F.

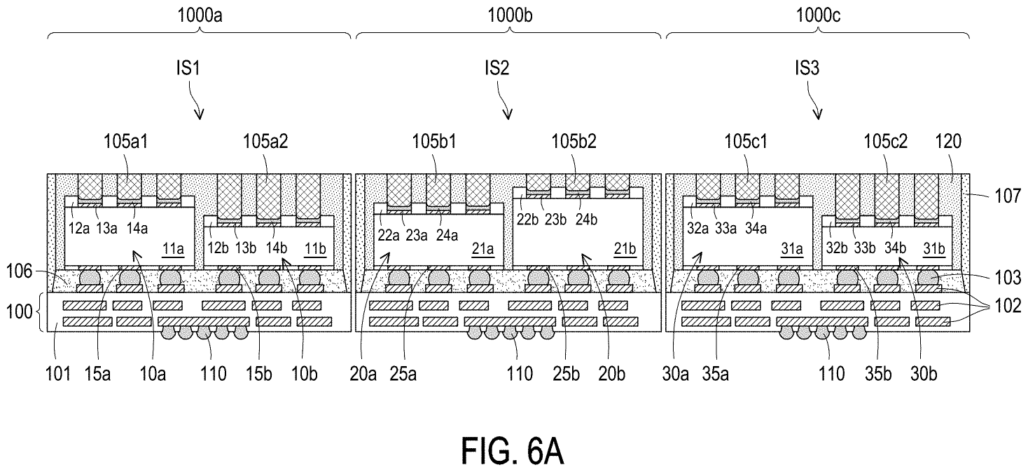

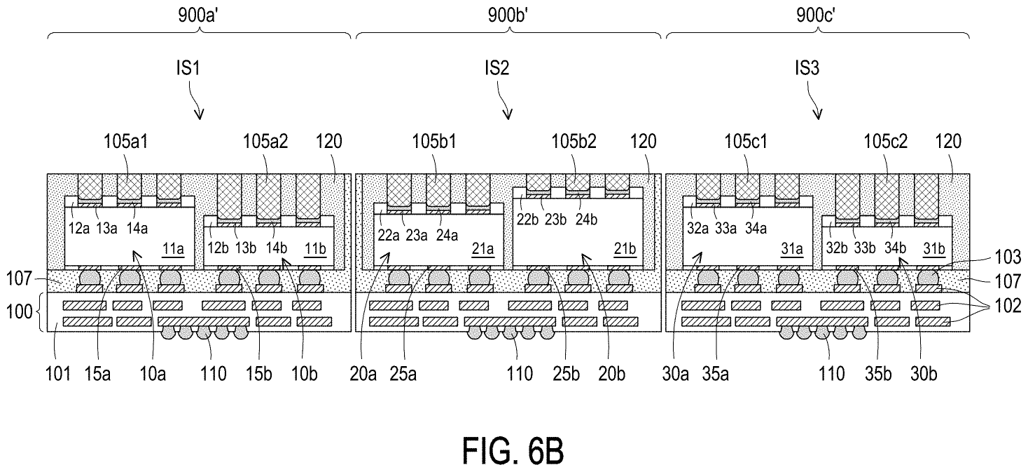

FIG. 6A to FIG. 6B are cross-sectional views illustrating package structures according to some other embodiments of the disclosure.

Referring to FIG. 6A, in some embodiments, package structures 1000a-1000c are similar to the package structures 900a-900c, except that the package structures 1000a-1000c further include underfill layers 106. In some embodiments, after the semiconductor structures IS1-IS3 are bonded to the RDL structure 100, and before forming the encapsulant 107, underfill layers 106 are formed to fill the spaces between the semiconductor structures IS1-IS3 and the RDL structure 100. Thereafter, the encapsulant 107 are formed to laterally encapsulate the semiconductor structures IS1-IS3 and the underfill layers 106.

In the embodiments shown in FIGS. 5F, 5G and 6A, the singulation process is performed to cut through the encapsulant 107, and the sidewalls of the encapsulant 120 are not exposed at the singulated package structures. However, the disclosure is not limited thereto.

For example, referring to FIG. 6B, package structures 900a′-900c′ are illustrated. In some embodiments, after the singulation process is performed, in one or more package structure of the package structures 900a′-900c′, one or more sidewall of the encapsulant 120 may be exposed. For example, in the package structure 900a′, one of the sidewalls of the encapsulant 120 is exposed and may be substantially aligned with the corresponding sidewall of the encapsulant 107, while another sidewall of the encapsulant 120 may be laterally encapsulated by the encapsulant 107. As another example, in the package structure 900c′, both opposite sidewalls of the encapsulant 120 are exposed and may be substantially aligned with corresponding sidewalls of the encapsulant 107.

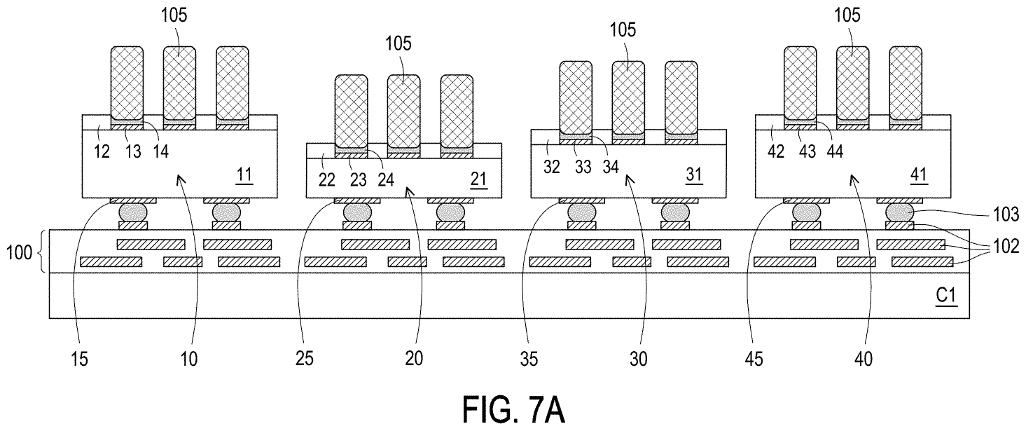

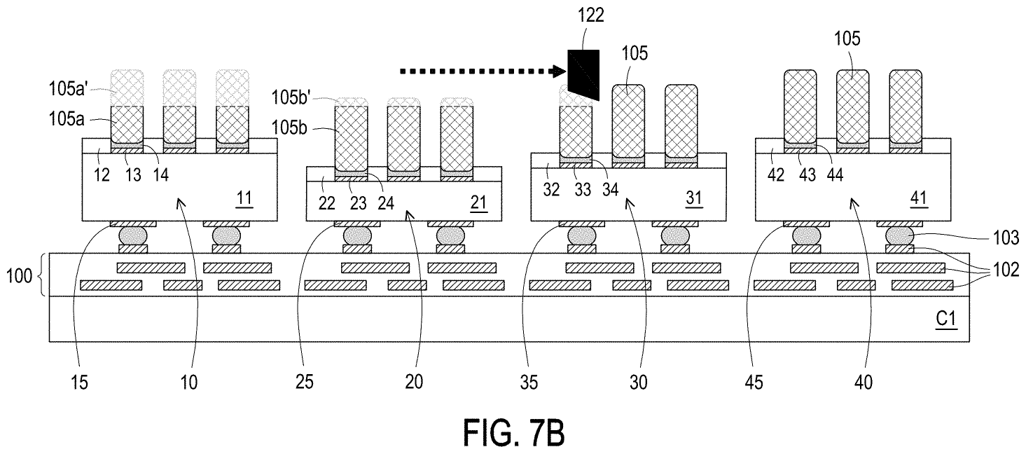

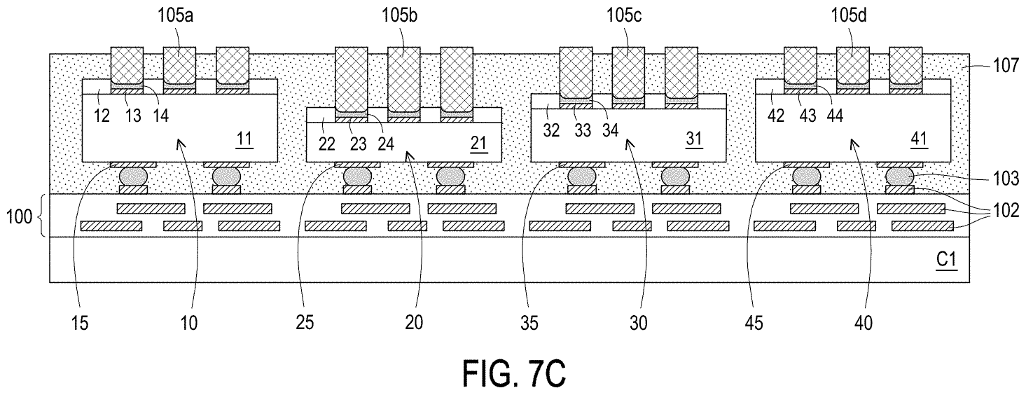

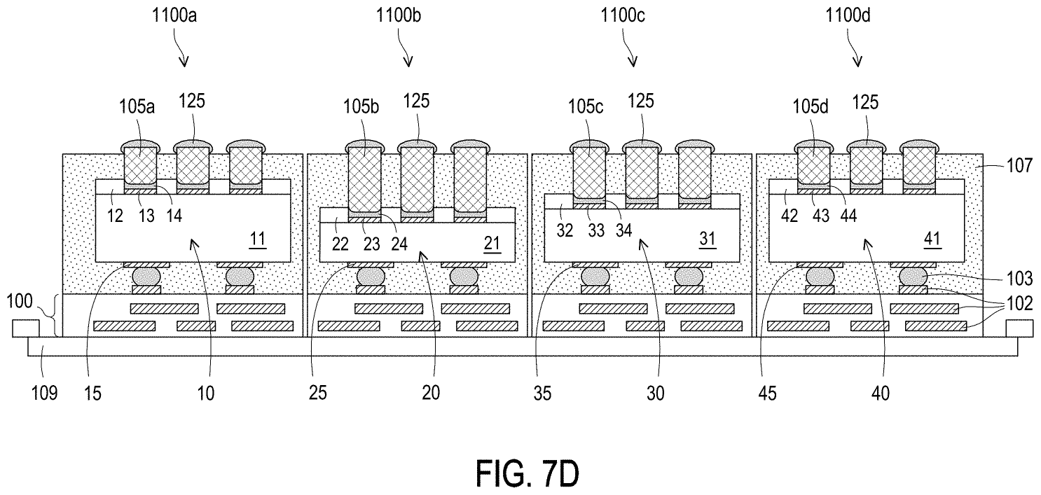

FIG. 7A to FIG. 7D are cross-sectional views illustrating a method of forming package structures according to some other embodiments of the disclosure. The present embodiment is similar to the foregoing embodiments, except that a different leveling process for the pillar structures is used.

Referring to FIG. 7A, similar to the embodiments described above, a plurality of semiconductor devices (e.g., semiconductor devices 10-40) are bonded to a RDL structure 100 over a carrier C1. The structure of the semiconductor device 40 is similar to those described with respect to the semiconductor device 10, which are not described again here. In some embodiments, the semiconductor devices 10-40 have different heights, and the top surfaces thereof are located at different level heights. Joint layers 14-44 are applied on the conductive features 13-43 of the semiconductor devices 10-40, respectively. A plurality of the pillar structures 105 are mounted to the semiconductor devices 10-40 through the joint layers 14-44, respectively.

Referring to FIG. 7B, in some embodiments, the pillar structure 105 are then planarized or leveled before forming an encapsulant material. For example, a cut process, such as a fly cut process may be performed to remove portions of the pillar structures 105, such that the remained pillar structures have top surfaces that are substantially level with each other. In some embodiments, the fly cut process may use mechanical force to cut portions of the pillar structures 105. For example, a mechanical component 122, such as a mechanical saw may be used to cut top portions of the pillar structures 105. FIG. 7B illustrates an intermediate structure during the fly cut process in which the pillar structures 105 on the semiconductor devices 10 and 20 have been cut, while the pillar structures 105 on the semiconductor devices 30 and 40 are to be cut. As shown in FIG. 7B, portions 105a′ and 105b′ of the pillar structures 105 over the semiconductor devices 10 and 20 are cut and removed by the mechanical component 122, while pillar structure 105a and 105b are remained on the semiconductor devices 10 and 20 and have substantially coplanar top surfaces. In some embodiments, the cut process may also be referred to as a leveling process or a planarization process.

Referring to FIG. 7C, after the cut process is performed, pillar structures 105a-105d are remained over the semiconductor devices 10-40, respectively. The top surfaces of the pillar structures 105a-105d are substantially level with each other. Thereafter, an encapsulant 107 is formed over the RDL structure 100 to encapsulate the semiconductor devices 10-40 and the pillar structures 105a-105d. In some embodiments, the encapsulant 107 includes a molding underfill or a molding compound, and the top surface of the encapsulant 107 may be formed to be lower than the top surfaces of the pillar structures 105a-105d, such that the top portions of the pillar structures 105a-105d are exposed. For example, the top surfaces and top portions of sidewalls of the pillar structures 105a-105d are exposed. Such a molding process for forming the encapsulant 107 may be referred to as an exposed molding process. In such a way, a planarization process (e.g., grinding and/or polishing, such as CMP) for removing excess portions of encapsulant material to expose the pillar structures may be not required, and the usage of molding material is reduced. However, the disclosure is not limited thereto. In alternative embodiments, processes similar to those described in the foregoing embodiments may be used to form the encapsulant. For example, an encapsulant material (not shown) may be formed over the RDL structure 100 to cover sidewalls and top surfaces of the semiconductor devices 10-40 and the pillar structures 105a-105d, thereafter, a planarization process (e.g., grinding and/or polishing, such as CMP) may be performed to remove excess portions of the encapsulant material over the top surfaces of the pillar structures 105a-105d. In such embodiment, the resulted encapsulant may have a top surface substantially level with the top surfaces of the semiconductor devices 10-40.

In the illustrated embodiment shown in FIG. 7C, the encapsulant 107 further extends to fill the spaces between the semiconductor devices 10-40 and the RDL structure 100, but the disclosure is not limited thereto. In some other embodiments, before forming the encapsulant 107, underfill layers (not shown) may be further formed to fill the spaces between the semiconductor devices 10-40 and the RDL structure 100, and sidewalls of the underfill layers would be laterally encapsulated by the subsequently formed encapsulant 107.

Referring to FIG. 7C and FIG. 7D, thereafter, the carrier C1 is released from the overlying structure, and the structure shown in FIG. 7C is mounted to a frame tape 109. In some embodiments, the structure is disposed on the frame tape 109 with the RDL structure 100 facing the frame tape 109. A plurality of connectors 125 may then be formed on the pillar structures 105a-105d and electrically connected to the semiconductor devices 10-40 through the pillar structures 105a-105d. The materials and forming method of the connectors 125 are similar to those of the above-described connectors 110, which are not described again here. Thereafter, a singulation process may be performed to singulate the package structures 1100a-1100d. The package structures 1100a-1100d may be removed from the frame tape 109 afterwards.

Referring to FIG. 7D, the package structures 1100a-1100d are similar to the package structures 500a-500c, except that the package structures 1100a-1100d include the connectors 125 disposed on the pillar structures 105a-105d. In some embodiments, there may be free of the connectors disposed on the bottom sides of the RDL structure 100. In some other embodiments, the package structures 1100a-1100d may also include connectors (e.g., connectors 110 shown in FIG. 1F) disposed on the bottom sides of the RDL structure 100.

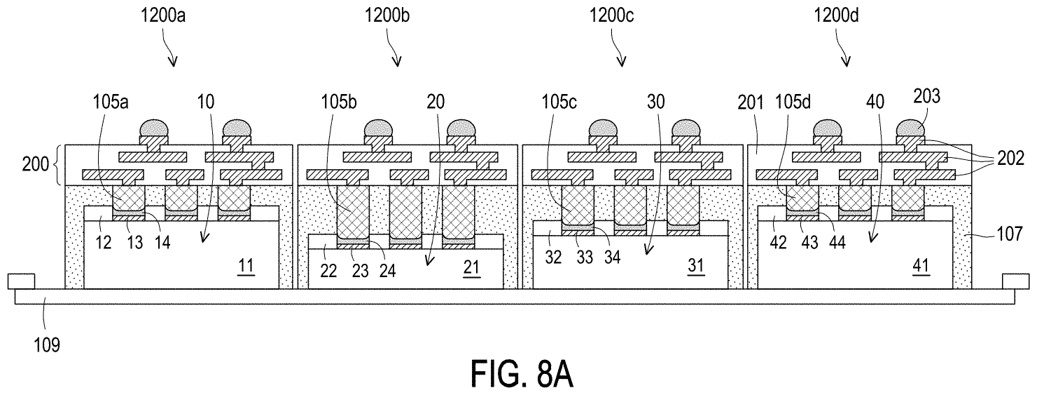

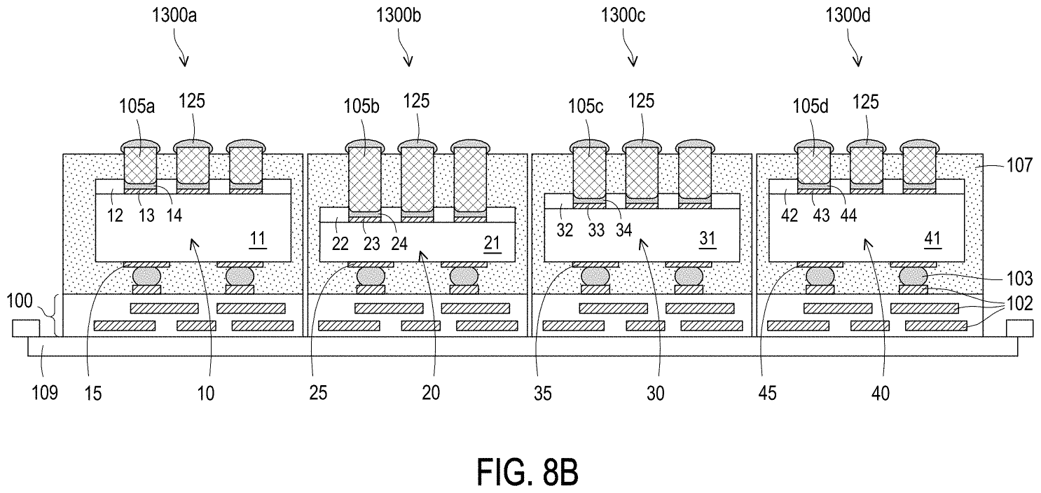

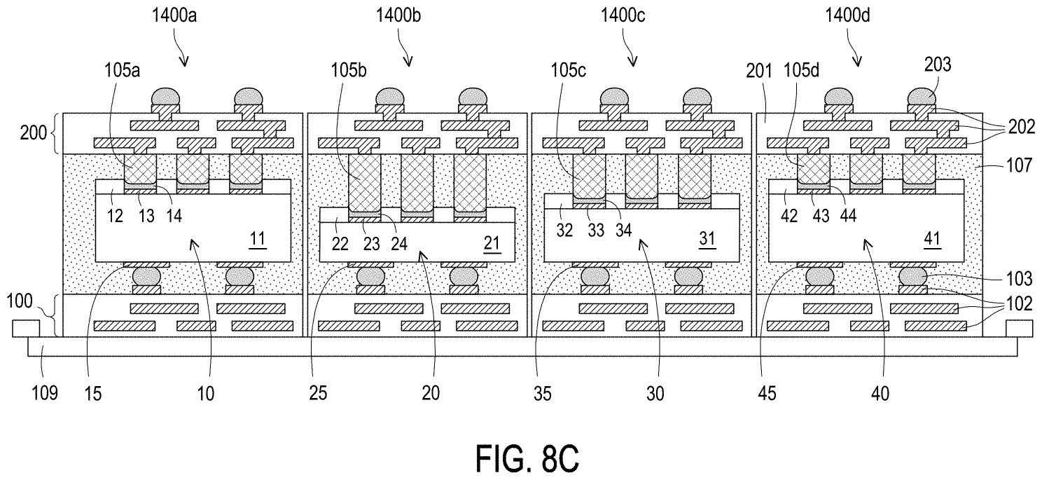

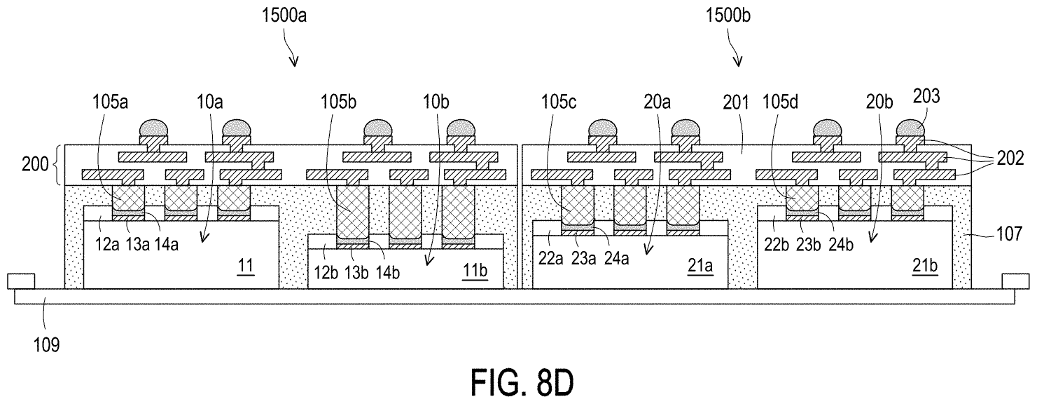

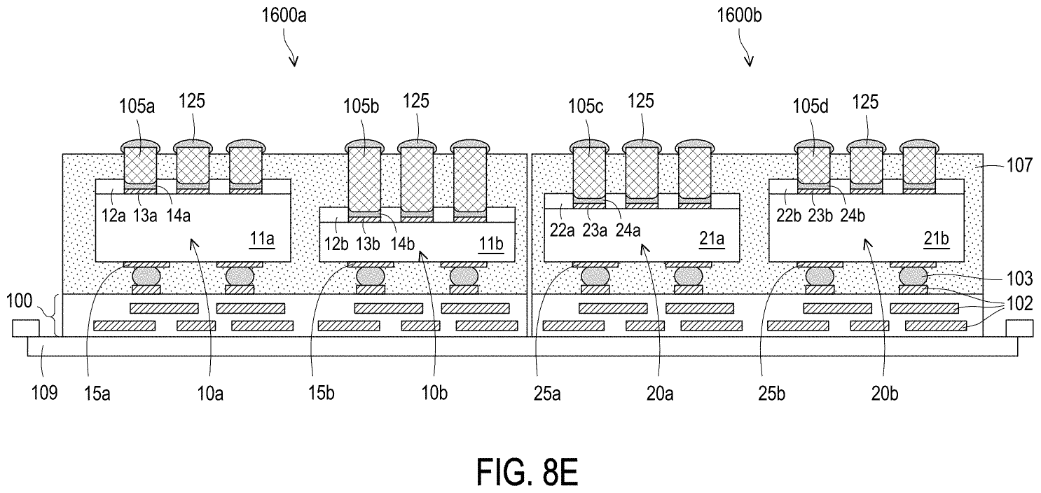

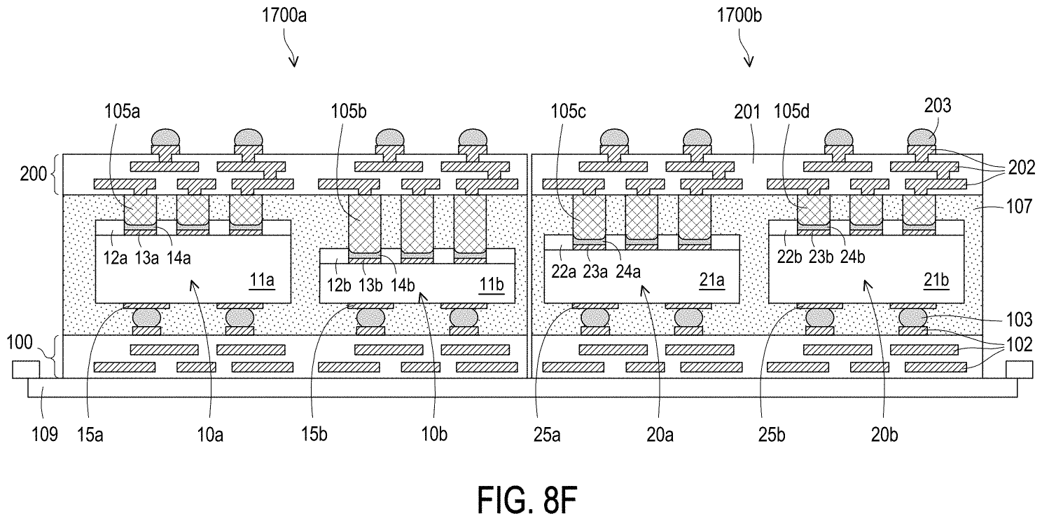

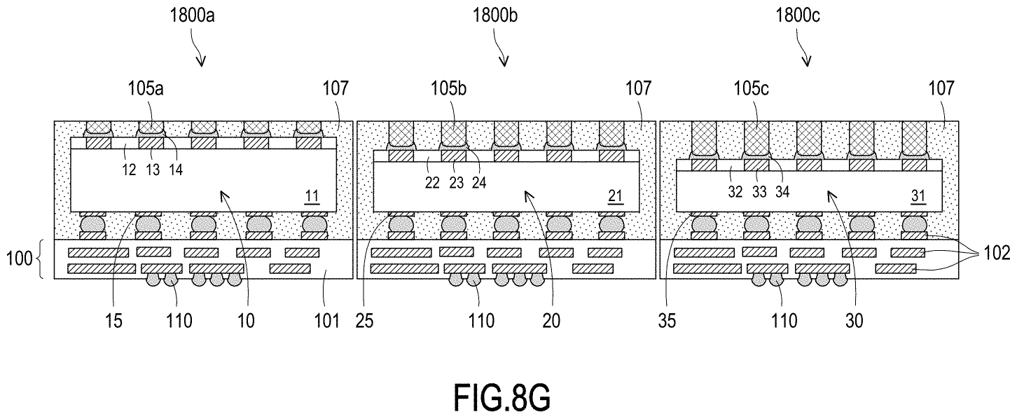

FIG. 8A to FIG. 8G are cross-sectional views illustrating package structures according to some other embodiments of the disclosure. In each of FIG. 8A to FIG. 8G, the illustrated package structures are formed in a same packaging process and have been singulated over a frame tape, and the package structures may be removed from the frame tape afterwards.

Referring to FIG. 8A, package structures 1200a to 1200d are illustrated. The package structures 1200a-1200d are similar to the package structures illustrated in the foregoing embodiment, except that the package structures 1200a-1200d include RDL structure 200 disposed on front side of the semiconductor devices 10-40. Herein, the “front side” of the semiconductor devices 10-40 refers to the side close to or including the pillar structures 105a-105d, and “back side” of the semiconductor devices 10-40 refer to the side opposite to the front side and farther from the pillar structures 105a-105d than the front side.

In some embodiments, the RDL structures 200 may be disposed on the semiconductor devices 10-40 and the respective encapsulant 107, and electrically connected to the semiconductor devices 10-40 through the pillar structures 105a-105d. The RDL structure 200 may include a dielectric structure 201 having a plurality of dielectric layers, and redistribution layers 202 are embedded in and/or protruded from the dielectric structure 201 and electrically connected to the respective pillar structures 105a-105d. In some embodiments, the redistribution layers 202 includes conductive vias and conductive traces that are connected to each other. The conductive vias may be disposed between the corresponding pillar structures and the conductive traces and between conductive traces in different tier, so as to provide electrical connection therebetween. The material and structure of the RDL structure 200 may be similar to those of the RDL structure 100, except that the RDL structure 200 further includes conductive vias landing on corresponding pillar structures 105a-105d.

Still referring to FIG. 8A, in some embodiments, a plurality of connectors 203 are formed on and electrically connected to the RDL structure 200. The connectors 203 may also be referred to as conductive terminals. The material of the connectors 203 may be selected from the same candidate materials of the connectors 110. In some embodiments in which the connectors 203 are solder regions, the topmost redistribution layer 102 may be or include a under-ball metallurgy (UBM) layer. In some embodiments, the semiconductor devices 10-40 may be free of conductive features disposed on second sides of the body structures 11-41. The bottom surfaces of the body structures 11-41 of the semiconductor devices 10-40 may be substantially level with the bottom surface of the encapsulant 107. However, the disclosure is not limited thereto.

Referring to FIG. 8B, package structures 1300a-1300d are illustrated. The package structures 1300a-1300d are similar to the package structures 1100a-1100d, except that, in the package structures 1300a-1300d, the top surfaces of the encapsulants 107 are substantially level with the top surfaces of the pillar structures 105a-105d. In some embodiments, the package structures 1300a-1300d include RDL structures 100 disposed on back sides of the semiconductor devices 10-40.

Referring to FIG. 8C, in some embodiments, package structures 1400a-1400d includes RDL structures 100 and 200 disposed on both front sides and back sides of the semiconductor devices 10-40. In some embodiments, at least one of the RDL structures 100 and 200 may be replaced by other package component, such as package substrate, circuit board, interposer, or the like. In some embodiments, a plurality of connectors 203 are disposed on the RDL structure 200, and there may be free of connectors disposed on the side (e.g., bottom side) of the RDL structure 100 opposite to the semiconductor devices 10-40, but the disclosure is not limited thereto. In some other embodiments, the package structures 1400a-1400d may further include connectors (e.g., connectors 110 shown in FIG. 1F) disposed on bottom sides of the RDL structures 100.

Referring to FIG. 8D, package structures 1500a and 1500b are illustrated. The package structures 1500a-1500b are similar to the package structures 1200a-1200d, except that the package structures 1500a and 1500b each include more than one semiconductor device that have different heights. For example, the package structure 1500a includes semiconductor devices 10a and 10b, pillar structures 105a and 105d respectively disposed on the semiconductor devices 10a and 10b, an encapsulant 107, a RDL structure 200 and connectors 203. The structure of the package structure 1500b is similar to that of the package structure 1500a.

In some embodiments, the semiconductor devices 10a and 10b have different heights, and the pillar structure 105a and 105b are disposed on the semiconductor devices 10a and 10b for compensating the height difference between the semiconductor devices 10a and 10b. For example, the height of the semiconductor device 10a is larger than that of the semiconductor device 10b, the bottom surfaces of the semiconductor devices 10a and 10b may be substantially level with each other, and the top surface of the semiconductor device 10a may be higher than the semiconductor device 10b. In such embodiments, the height of the pillar structure 105a on higher semiconductor device 10a is less than the pillar structure 105b on lower semiconductor device 10b, such that the top surface of the semiconductor device 10a with pillar structures 105a disposed thereon is substantially level with the top surface of the semiconductor device 10b with pillar structures 105b disposed thereon.

The encapsulant 107 encapsulate sidewalls and top surfaces of the semiconductor devices 10a and 10b and sidewalls of the pillar structures 105a and 105b. In some embodiments, the top surface of the encapsulant 107 is substantially level with the top surfaces of the pillar structures 105a and 105b. The RDL structure 200 is disposed over the semiconductor devices 10a and 10b and electrically connected to the semiconductor devices 10a and 10b through the pillar structures 1105a and 105b. The connectors 203 are disposed over the RDL structure 200 and electrically connected to the semiconductor devices 10a and 10b through the RDL structure 200.

Referring to FIG. 8E, package structure 1600a-1600b are similar to the package structures 1300a-1300d, except that the package structures 1600a and 1600b each include more than one semiconductor devices having different heights. For example, the package structure 1600a includes semiconductor devices 10a and 10b having different heights, and pillar structures 105a and 105b with different heights are disposed on the semiconductor devices 10a and 10b for compensating the height difference between the semiconductor devices 10a and 10b. The structure of the package structure 1600b is similar to that of the package structure 1600a, which is not described again here.

Referring to FIG. 8F, package structures 1700a-1700b are similar to the package structures 1400a-1400d, except that the package structures 1700a-1700b each include more than one semiconductor device having different heights, and pillar structures are disposed on the semiconductor devices for compensating the height difference between the semiconductor devices.

In the foregoing embodiments, the top surface of the conductive features and the joint layers are formed to have top surfaces lower than the top surface of the passivation layer, and pillar structures are disposed to have bottom surfaces lower than the top surface of the passivation layers, but the disclosure is not limited thereto. As shown in FIG. 8G, in some embodiments, package structures 1800a-1800c are similar to the package structures 500a-500c, except that the joint layers 14-34 protrude from the top surfaces of the passivation layers 12-32, and the pillar structures 105a-105c disposed on the joint layers 14-34 have bottom surfaces higher than the top surfaces of the passivation layers 12-32. The joint layers 14-34 cover the bottom surfaces of the pillar structures 105a-105c and may further extend to cover portions of the sidewalls of the pillar structures 105a-105c. In some embodiments, the top surfaces of the conductive features 13-33 may be substantially level with the top surfaces of the passivation layers 12-32. However, the disclosure is not limited thereto. In some other embodiments, the top surfaces of the conductive features 13-33 may be lower than or higher than the top surfaces of the passivation layers 2-32. In some other embodiments, the bottom surfaces of the pillar structures 105a-105c may be substantially level with the top surfaces of the passivation layers 12-32.

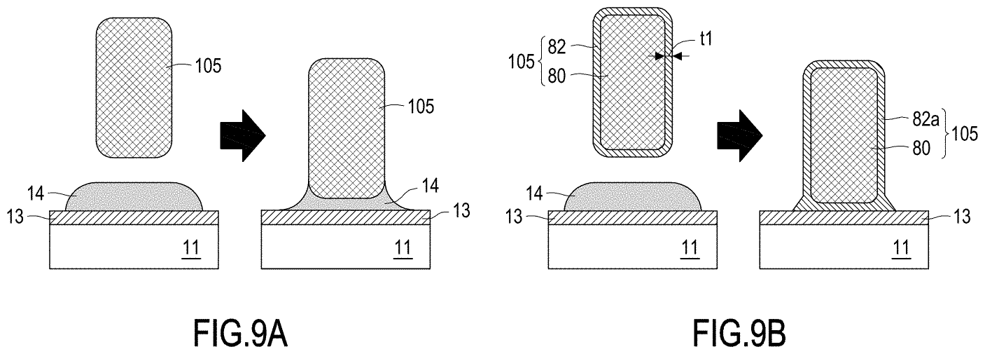

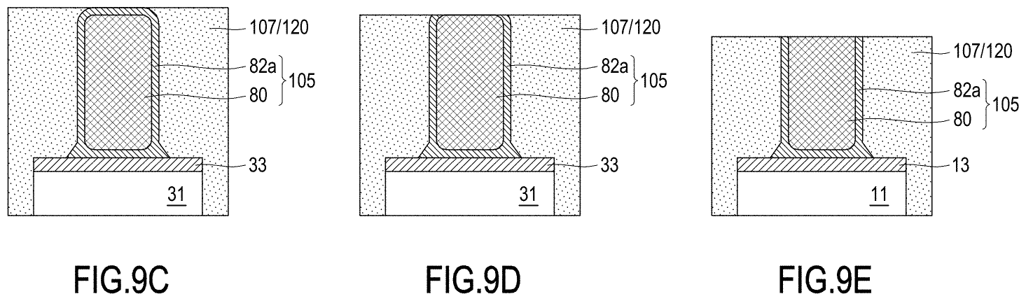

FIG. 9A and FIG. 9B are enlarged schematic views illustrating the mounting of the pillar structure 105 to the semiconductor device according to various embodiments of the disclosure. For the sake of brevity, merely the body structure 11 and the conductive feature 13 of the semiconductor device is shown in FIG. 9A and FIG. 9B. It should be understood that, the mounting method of the pillar structure 105 illustrated in FIG. 9A and FIG. 9B may be applied to any of the above-described embodiments.

Referring to FIG. 9A, as mentioned above, in some embodiments, the pillar structure 105 may be a metallic pillar, such as copper pillar. The joint layer 14 may be solder paste, silver paste, copper paste, glue such as conductive glue, or the like, and the pillar structure 105 is disposed on the joint layer 14 followed by a reflow process, such that the pillar structure 105 is connected to the conductive features 13 through the joint layer 14. In some embodiments, the pillar structure 105 may be a homogeneous structure and free of coating layer thereon. However, the disclosure is not limited thereto.

Referring to FIG. 9B, in some embodiments, the pillar structure 105 may include a pillar (e.g., conductive pillar) 80 and a coating layer 82 disposed on the surfaces of the pillar 80. The pillar 80 may be or include a metallic pillar, such as a copper pillar. The coating layer 82 may include a metal layer, such as Sn. In some embodiments, the coating layer 82 is a solder layer. The coating layer 82 covers and surrounds the surfaces (e.g., top surface, bottom surface and sidewalls) of the pillar 80. The thickness t1 of the coating layer 82 may range from 0.1 μm to 20 μm, for example. In the present embodiment, the joint layer 14 may be or include flux material, although solder paste, silver paste, copper paste, glue such as conductive glue, or the like may also be used. The pillar structure 105 is disposed on the joint layer 14 followed by performing a reflow process. In some embodiments in which the coating layer 82 include a solder layer and the joint layer 14 includes a flux material, during the reflow process, the flux material 14 is reacted with the coating layer 82 to facilitate the bonding process (i.e., the bonding of the pillar structure 105 to the semiconductor device). As such, a coating layer 82a is formed. The coating layer 82a may include a coating portion surrounding the pillar 80, and a joint portion disposed between the pillar 80 and the conductive feature 13. In other word, during the reflow process, the coating layer 82 may be merged with the joint layer 14.

FIG. 9C to FIG. 9E are enlarged schematic views illustrating the position relationship of the encapsulant and the pillar structure having coating layer according to various embodiments of the disclosure.

Referring to FIG. 9C, in some embodiments, during the planarization process (e.g., FIG. 1C-FIG. 1D), the planarization process may stop on the top surface of some pillar structures 105 (e.g., pillar structure 105c on lowest semiconductor device 30 shown in FIG. 1D), and the coating layer 82a may be not removed or partially removed, with the top surface of the pillar 80 being covered by the coating layer 82a. After the planarization process, the top surface of the pillar structure 105 (e.g., the top surface of the coating layer 82a) may be substantially level with the top surface of the encapsulant 107, and top surface of pillar 80 is lower than the top surfaces of the encapsulant and the coating layer. The coating layer 82 is interposed between the pillar 80 and the encapsulant 107 and covers the top surface and sidewalls of the pillar 80.

Referring to FIG. 9D, in some embodiments, during the planarization process (e.g., FIG. 1C-FIG. 1D), the planarization process may stop on the top surface of the pillar 80 of some pillar structures 105 (e.g., pillar structure 105b/105c on lower semiconductor device 20/30 shown in FIG. 1D), and the coating layer 82a may be partially removed, and the top surface of the pillar 80 is exposed. After the planarization process is performed, the top surface of the coating layer 82a, the top surface of the pillar 80 and the top surface of the encapsulant 107 may be substantially level with each other. In some embodiments, the rounding corner of the pillar 80 may be remained and covered by the coating layer 82a.

Referring to FIG. 9E, in some embodiments, during the planarization process (e.g., FIG. 1C-FIG. 1D), the planarization process may remove portions of the coating layer 82a and the pillar 80 of the pillar structure 105. After the planarization process is performed, the top surfaces of the coating layer 82a and the pillar 80 of the pillar structure 105 may be substantially level with the top surface of the encapsulant 107.

In some embodiments in which the package structure includes more than one semiconductor device and the pillar structures each includes a coating layer, the position relation between the encapsulant and different pillar structures on different semiconductor devices may be different. For example, referring to FIG. 3E, FIG. 5F and FIGS. 9C-9E, in the package structure 800a or 900a, the position relation between the pillar structure 105a1 and the encapsulant 107/120 may be similar to that is shown in FIG. 9D or FIG. 9E (in which the coating layer over the pillar may be removed by the planarization process), while the position relation between the pillar structure 105a2 and the encapsulant 107/120 may be similar to that is shown in FIG. 9C or FIG. 9D (in which the coating layer over the pillar may be not removed or partially removed). However, the disclosure is not limited thereto. In some other embodiments, the position relation between the encapsulant and different pillar structures on different semiconductor devices may be similar. For example, all the coating layers on the pillars of different pillar structures may be removed by the planarization process.

In the embodiments of the disclosure, pillar structures are disposed on the semiconductor devices for compensating the height/thickness difference between the semiconductor devices. Through disposing the pillar structures and subsequent planarization process, the thickness variation of the reconstructed semiconductor devices may be reduced, for example, to 0. Therefore, extra thickness measurement and sorting process before packaging process may be not required and may be omitted. On the other hand, with the pillar structures disposed on the semiconductor devices, the process window for the planarization process is increased. After the planarization process is performed, all of the pillar structures on different semiconductor devices may be exposed and serve as the external connections of the semiconductor devices. As such, the yield of the manufacturing process is increased.

In accordance with some embodiments of the disclosure, a package structure includes a semiconductor device including a conductive feature, a joint layer, a pillar structure, an encapsulant and a RDL structure. The joint layer is disposed on the conductive feature. The pillar structure is disposed on and coupled to the semiconductor device through the joint layer. The encapsulant laterally encapsulates the semiconductor device and the pillar structure. The RDL structure is electrically connected to the semiconductor device.

In accordance with alternative embodiments of the disclosure, a package structure includes a first semiconductor device and a second semiconductor device having different heights, a first pillar structure, a second pillar structure, a first encapsulant and a package component. The first pillar structure is disposed on the first semiconductor device. The second pillar structure is disposed on the second semiconductor device, and a top surface of the first pillar structure is level with a top surface of the second pillar structure. The first encapsulant laterally encapsulates the first semiconductor device, the second semiconductor device, the first pillar structure and the second pillar structure. The package component is electrically connected to the first semiconductor device and the second semiconductor device.

In accordance with some embodiments of the disclosure, a method of forming a package structure includes: providing a first semiconductor device and a second semiconductor device having different heights; bonding a first pillar structure and a second pillar structure to the first semiconductor device and the second semiconductor device, respectively; planarizing top surfaces of the first pillar structure and the second pillar structure; forming an encapsulant to encapsulate the first semiconductor device, the second semiconductor device, the first pillar structure and the second pillar structure; and electrically connecting a package component to the first semiconductor device and the second semiconductor device.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A package structure, comprising:
a semiconductor device comprising a conductive feature;
a joint layer, disposed on the conductive feature;
a pillar structure, disposed on and coupled to the semiconductor device through the joint layer;
an encapsulant, laterally encapsulating the semiconductor device and the pillar structure; and
a redistribution layer (RDL) structure, electrically connected to the semiconductor device.

2. The package structure of claim 1, wherein a top surface of the encapsulant is level with or lower than a top surface of the pillar structure.

3. The package structure of claim 1, wherein the joint layer is disposed between the pillar structure and the conductive feature of the semiconductor device.

4. The package structure of claim 3, wherein the joint layer further extends to cover a bottom corner or a portion of a sidewall of the pillar structure.

5. The package structure of claim 1, wherein the pillar structure comprises a pillar and a coating layer surrounding the pillar, and the coating layer is merged with the joint layer.

6. The package structure of claim 1, wherein the RDL structure is disposed on the pillar structure and electrically connected to the semiconductor device through the pillar structure.

7. The package structure of claim 1, wherein the pillar structure is disposed on a first side of the semiconductor device, and the RDL structure is disposed on a second side of the semiconductor device opposite to the first side.

8. The package structure of claim 7, further comprising an underfill layer, disposed to fill a space between the semiconductor device and the RDL structure, and the underfill layer is laterally encapsulated by the encapsulant.

9. The package structure of claim 1, further comprising an additional encapsulant, disposed between the semiconductor device and the encapsulant, and between the pillar structure and the encapsulant, wherein the additional encapsulant is encapsulated by the encapsulant.

10. A package structure, comprising:
a first semiconductor device and a second semiconductor device having different heights;
a first pillar structure, disposed on the first semiconductor device;
a second pillar structure, disposed on the second semiconductor device, wherein a top surface of the first pillar structure is level with a top surface of the second pillar structure;
a first encapsulant, laterally encapsulating the first semiconductor device, the second semiconductor device, the first pillar structure and the second pillar structure; and
a package component, electrically connected to the first semiconductor device and the second semiconductor device.

11. The package structure of claim 10, wherein a top surface of the first semiconductor device is higher than a top surface of the second semiconductor device, and a height of the first pillar structure is less than a height of the second pillar structure.

12. The package structure of claim 10, further comprising a second encapsulant, encapsulating sidewalls and top surfaces of the first semiconductor device and the second semiconductor device and sidewalls of the first pillar structure and the second pillar structure, and the second encapsulant is encapsulated by the first encapsulant.

13. The package structure of claim 10, wherein the first and second pillar structures are disposed on a first side of the first and second semiconductor devices, and the package component is disposed on a second side of the first and second semiconductor devices opposite to the first side, wherein the first encapsulant is further disposed to fill a space between the first and second semiconductor devices and the package component.

14. The package structure of claim 10, further comprising an underfill layer, disposed to fill a space between the first and second semiconductor devices and the package component, and the underfill layer is laterally encapsulated by the first encapsulant.

15. The package structure of claim 10, wherein at least one of the first and second pillar structures comprises a pillar and a coating layer surrounding the pillar, the coating layer is disposed between the pillar and the first encapsulant, and a top surface of the pillar is level with or lower than a top surface of coating layer.

16. A method of forming a package structure, comprising:
providing a first semiconductor device and a second semiconductor device having different heights;
bonding a first pillar structure and a second pillar structure to the first semiconductor device and the second semiconductor device, respectively;
planarizing top surfaces of the first pillar structure and the second pillar structure;
forming an encapsulant to encapsulate the first semiconductor device, the second semiconductor device, the first pillar structure and the second pillar structure; and
electrically connecting a package component to the first semiconductor device and the second semiconductor device.

17. The method of claim 16, wherein the first semiconductor device and the second semiconductor device may be disposed within a same package region or different package regions.

18. The method of claim 16, wherein after forming the first encapsulant and before electrically connecting the package component to the first and second semiconductor devices, further comprising performing a singulation process to form a semiconductor structure comprising at least one of the first semiconductor device and the second semiconductor device, and the package component is electrically connected to the semiconductor structure.

19. The method of claim 16, wherein planarizing top surfaces of the first pillar structure and the second pillar structure comprises performing a cut process to remove portions of the first pillar structure and the second pillar structure, and the encapsulant is formed after performing the cut process.

20. The method of claim 16, wherein planarizing top surfaces of the first pillar structure and the second pillar structure and forming the encapsulant comprises:
forming an encapsulant material to cover the first and semiconductor devices and the first and second pillar structures; and
performing a planarization process to remove portions of the encapsulant material and portions of the first and second pillar structures, such that the top surfaces of the first and second pillar structures are planarized and exposed by the encapsulant.
